(19) United States
(12) Patent Application Publication
(10) Pub. No.: US 2021/0132498 A1
(43) Pub. Date: May 6, 2021

(54) HARD-MASK FORMING COMPOSITION AND METHOD FOR MANUFACTURING ELECTRONIC COMPONENT

(71) Applicant: TOKYO OHKA KOGYO CO., LTD., Kawasaki-shi (JP)

(72) Inventors: Junichi Tsuchiya, Kawasaki-shi (JP); Keiichi Ibata, Kawasaki-shi (JP)

(21) Appl. No.: 17/062,330

(22) Filed: Oct. 2, 2020

(30) Foreign Application Priority Data
Oct. 31, 2019 (JP) 2019-199340

(51) Int. Cl. G03F 7/11; H01L 21/308; H01L 21/48; H01L 21/027; G03F 7/09

(52) U.S. Cl. CPC G03F 7/11; H01L 21/3081; G03F 7/094; H01L 21/4828; H01L 21/0271; H01L 21/3086

(57) ABSTRACT

A hard-mask forming composition including a resin (P1) containing a structural unit (u11) represented by General Formula (u11-1), and a resin (P2) containing an aromatic ring and a polar group, provided that the resin (P1) is excluded from the resin (P2), wherein R¹¹ represents an aromatic hydrocarbon group which may have a substituent, Rp¹¹ is an aldehyde group, a group represented by Formula (u-r-1), a group represented by Formula (u-r-2), or a group represented by Formula (u-r-3)

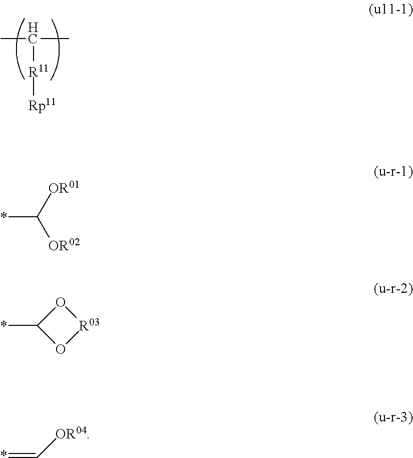

### BACKGROUND OF THE INVENTION

### Field of the Invention

The present invention relates to a hard-mask forming composition and a method for manufacturing an electronic component.

Priority is claimed on Japanese Patent Application No. 2019-199340, filed on Oct. 31, 2019, the content of which is incorporated herein by reference.

### Description of Related Art

Generally, in semiconductor manufacturing, a laminate in which a resist film is formed on a substrate, such as a silicon wafer, is subjected to processing including dry etching, for example, a treatment in which a resist film is selectively exposed to form a resist pattern on the resist film, and dry etching is performed using thereof as a mask, thereby forming a pattern on the substrate.

As a pattern forming method using a resist film, a three-layer resist method is known (for example, see Japanese Unexamined Patent Application First Publication No. 2001-051422). The three-layer resist method is that, first, an organic hard mask layer is formed using an organic material on a support, an inorganic hard mask layer is formed thereon using an inorganic material, and then a resist film is further formed on the inorganic hard mask layer. Subsequently, a resist pattern is formed by typical lithography, an inorganic hard mask pattern is formed by etching the inorganic hard mask layer with the resist pattern as a mask, and then an organic hard mask pattern is formed by etching the organic hard mask layer with the inorganic hard mask layer pattern as a mask. Then, the support is processed by being etched with the organic hard mask pattern as a mask.

Additionally, a two-layer resist method with fewer steps than the three-layer resist method has also been proposed (for example, see Japanese Unexamined Patent Application First Publication Nos. S61-239243 and S62-025744). The two-layer resist method is that the organic hard mask layer is provided on the support in the same manner as in the three-layer resist method, and then the resist film is provided on the organic hard mask layer. Subsequently, the resist pattern is formed by typical lithography, and the organic hard mask pattern is formed by etching the organic hard mask layer with the resist pattern as a mask. Then, the support is processed by being etched with the organic hard mask pattern as a mask.

As a method of forming the organic hard mask layer, a chemical vapor deposition method (hereinafter, sometimes referred to as a CVD method) is known in the related art. The CVD method uses amorphous carbon as a hard-mask forming material and has problems including slow throughput and expensive equipment investment.

Therefore, film formation by spin-on-coating has been introduced in recent years (for example, see Japanese Unexamined Patent Application First Publication No. 2015-091775), for which organic hard-mask forming materials applicable to the method has been proposed. The spin-on-coating has advantageous effects of high throughput and usability of the existing spin coater as compared with the CVD method.

As the organic hard-mask forming material, for example, a composition containing a specific resin containing an aromatic ring and a low molecular weight crosslinking agent is used.

### CITATION LIST

### Patent Literature

[Patent Literature 1] Japanese Unexamined Patent Application First Publication No. 2001-051422

[Patent Literature 2] Japanese Unexamined Patent Application First Publication No. S61-239243

[Patent Literature 3] Japanese Unexamined Patent Application First Publication No. S62-025744

[Patent Literature 4] Japanese Unexamined Patent Application First Publication No. 2015-091775

### SUMMARY OF THE INVENTION

In the hard-mask forming material in the related art, due to the low molecular weight crosslinking agent, there are cases where outgassing is generated when the hard mask layer is formed on the support, and cracks are generated in the hard mask layer.

The present invention is made in view of the problems described above, and an object of the present invention is to provide a method for manufacturing a hard-mask forming composition having low outgassing property and excellent crack resistance and a method for manufacturing an electronic component using the hard-mask forming composition with consideration of such problems.

The present invention adopts the following composition in order to solve the problems.

That is, a first aspect of the present invention provides a hard-mask forming composition comprising: a resin (P1) containing a structural unit (u11) represented by General Formula (u11-1); and a resin (P2) containing an aromatic ring and a polar group (here, excluding the resin (P1)).

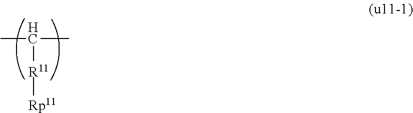

[In Formula (u11-1), R¹¹ is an aromatic hydrocarbon group which may have a substituent. Rp¹¹ is an aldehyde group, a group represented by Formula (u-r-1), a group represented by Formula (u-r-2), or a group represented by Formula (u-r-3).]

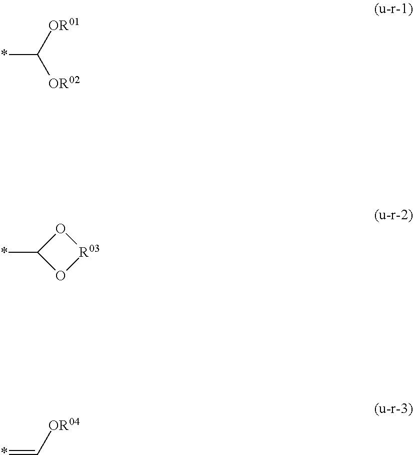

[In Formula (u-r-1), R⁰¹ and R⁰² each independently are a monovalent hydrocarbon group. In Formula (u-r-2), R⁰³ is a divalent hydrocarbon group. In Formula (u-r-3), R⁰⁴ is a monovalent hydrocarbon group. The symbol * represents a bonding site.]

A second aspect of the present invention is a method for manufacturing an electronic component including: forming a hard mask layer (m1) on a support using the hard-mask forming composition according to the first aspect; and processing the support using the hard mask layer (m1) as a mask.

A third aspect of the present invention provides a method for manufacturing an electronic component, including: forming a hard mask layer (m1) on a support using the hard-mask forming composition according to the first aspect; forming a hard mask layer (m2) made of an inorganic material on the hard mask layer (m1); forming a resist film on the hard mask layer (m2); exposing the resist film to light and developing the exposed resist film to form a resist pattern on the hard mask layer (m2); etching the hard mask layer (m2) using the resist pattern as a mask to form an inorganic pattern; etching the hard mask layer (m1) using the inorganic pattern as a mask to form a resin pattern; and processing the support using the resin pattern as a mask.

A fourth aspect of the present invention provides a method for manufacturing an electronic component, including: forming a hard mask layer (m1) on a support using the hard-mask forming composition according to the first aspect; forming an inorganic pattern made of an inorganic material on the hard mask layer (m1); etching the hard mask layer (m1) using the inorganic pattern as a mask to form a resin pattern; and processing the support using the resin pattern as a mask.

According to the present invention, it is possible to provide a hard-mask forming composition having low outgassing property and excellent crack resistance, and a method for manufacturing an electronic component using the hard-mask forming composition.

### BRIEF DESCRIPTION OF THE DRAWINGS

FIG. 1 is a cross-sectional view showing an exemplified support used in a method for manufacturing an electronic component according to an embodiment of the present invention.

FIG. 2 is a view illustrating an exemplified process of forming a hard mask layer (m1) in the method for manufacturing an electronic component according to the embodiment of the present invention.

FIG. 3 is a view illustrating an exemplified process of forming a hard mask layer (m2) in the method for manufacturing an electronic component according to the embodiment of the present invention.

FIG. 4 is a view illustrating an exemplified process of forming a resist film in the method for manufacturing an electronic component according to the embodiment of the present invention.

FIG. 5 is a view illustrating an exemplified process of forming a resist pattern in the method for manufacturing an electronic component according to the embodiment of the present invention.

FIG. 6 is a view illustrating an exemplified process of forming an inorganic pattern in the method for manufacturing an electronic component according to the embodiment of the present invention.

FIG. 7 is a view illustrating an exemplified process of forming a resin pattern in the method for manufacturing an electronic component according to the embodiment of the present invention.

FIG. 8 is a view illustrating an exemplified process of processing a support in the method for manufacturing an electronic component according to the embodiment of the present invention.

### DETAILED DESCRIPTION OF THE INVENTION

In the specification and claims of the present invention, the term “aliphatic” is a relative concept to aromatic, and is defined to mean a group, a compound, or the like, which has no aromaticity.

The term “alkyl group” is intended to encompass linear, branched and cyclic monovalent saturated hydrocarbon groups, unless otherwise specified. The same definition applies to an alkyl group in an alkoxy group. The same definition applies to an alkyl group in an alkoxy group.

The term “alkylene group” is intended to encompass linear, branched, and cyclic divalent saturated hydrocarbon groups, unless otherwise specified.

The term “halogenated alkyl group” refers to a group in which a part or all of the hydrogen atoms of the alkyl group are substituted with halogen atoms, and examples of the halogen atom include a fluorine atom, a chlorine atom, a bromine atom, and an iodine atom.

The term “fluorinated alkyl group” or “fluorinated alkylene group” refers to a group in which a part or all of hydrogen atoms of an alkyl group or an alkylene group are substituted with fluorine atoms.

The term “structural unit” refers to a monomer unit (monomer unit) constituting a polymer compound (resin, polymer, or copolymer).

The expression “may have a substituent” includes both cases where a hydrogen atom (—H) is substituted with a monovalent group, and where a methylene group (—CH₂—) is substituted with a divalent group.

The term “exposure (exposing)” is a concept that includes general radiation irradiations.

In the detailed description and claims of the present invention, in the specification and claims of the present invention, some structures represented by a chemical formula have an asymmetric carbon, and there may be enantiomers and diastereomers. Those isomers are collectively represented by one formula. The isomers may be used alone or as a mixture.

<Hard-Mask Forming Composition>

The hard-mask forming composition according to the first aspect of the present invention is a composition for forming a hard mask used in lithography. The hard-mask forming composition of the present embodiment includes a resin (P1) having a structural unit (u11) represented by General Formula (u11-1) and a resin (P2) containing an aromatic ring and a polar group (here, except for the resin (P1)).

<<Resin (P1)>>

The resin (P1) has a structural unit (u11) represented by General Formula (u11-1).

Structural Unit (u11)

The structural unit (u11) is a structural unit represented by General Formula (u11-1).

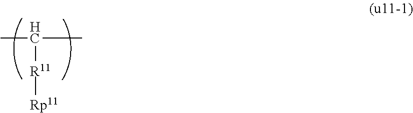

[In Formula (u11-1), R¹¹ is an aromatic hydrocarbon group which may have a substituent. Rp¹¹ is an aldehyde group, a group represented by Formula (u-r-1), a group represented by Formula (u-r-2), or a group represented by Formula (u-r-3).]

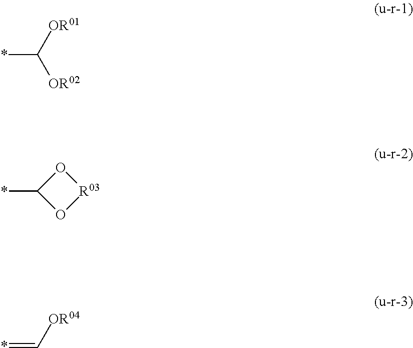

[In Formula (u-r-1), R⁰¹ and R⁰² each independently are a monovalent hydrocarbon group. In Formula (u-r-2), R⁰³ is a divalent hydrocarbon group. In Formula (u-r-3), R⁰⁴ is a monovalent hydrocarbon group. The symbol * represents a bonding site.]

In Formula (u11-1), R¹¹ is an aromatic hydrocarbon group which may have a substituent. Examples of the substituent include a hydroxy group, a carbonyl group, an alkoxy group, a halogen atom, an alkyl group, an alkenyl group, an alkynyl group, and the like.

The aromatic hydrocarbon group for R¹¹ has preferably 6 to 30 carbon atoms, and more preferably 6 to 25 carbon atoms. The aromatic hydrocarbon group for R¹¹ is a hydrocarbon group which has at least one aromatic ring. The aromatic ring is not particularly limited as long as it is a cyclic conjugated system having 4n+2π electrons, and may be monocyclic or polycyclic. The aromatic ring has preferably 5 to 20 carbon atoms, more preferably 5 to 18 carbon atoms, and still more preferably 6 to 16 carbon atoms.

Specific examples of the aromatic ring include an aromatic hydrocarbon ring such as benzene, naphthalene, anthracene, phenanthrene, pyrene, or the like; an aromatic heterocyclic ring in which a part of carbon atoms constituting the aromatic hydrocarbon ring is substituted with hetero atoms; and the like. Examples of the hetero atom in the aromatic heterocyclic ring include an oxygen atom, a sulfur atom, a nitrogen atom, and the like. Specific examples of the aromatic heterocyclic ring include a pyrrolidine ring, a pyridine ring, a thiophene ring, and the like.

Specific examples of the aromatic hydrocarbon group for R¹¹ include a group (an aryl group or a heteroaryl group) obtained by removing one hydrogen atom from the aromatic hydrocarbon ring or the aromatic heterocyclic ring; a group obtained by removing one hydrogen atom from an aromatic compound (for example, biphenyl, fluorene, and the like) containing two or more aromatic rings; a group (for example, an arylalkyl group such as benzyl group, phenethyl group, 1-naphthylmethyl group, 2-naphthylmethyl group, 1-naphthylethyl group, 2-naphthylethyl group, and the like) in which one of hydrogen atoms of the aromatic hydrocarbon ring or the aromatic heterocyclic ring is substituted with an alkylene group; and the like. An alkylene group to be bonded to the aromatic hydrocarbon ring or the aromatic heterocyclic ring has preferably 1 to 4 carbon atoms, more preferably 1 to 2 carbon atoms, and particularly preferably 1 carbon atom.

Specific examples of R¹¹ in Formula (u11-1) are shown below. The symbol * represents a bonding site.

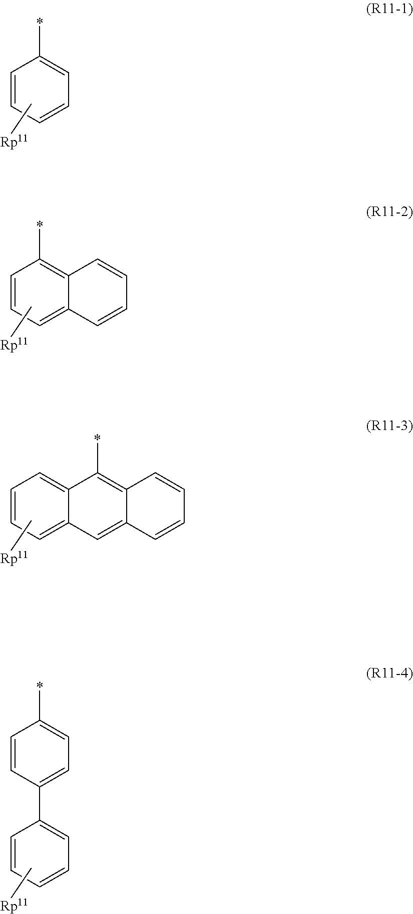

In Formula (u11-1), Rp¹¹ represents an aldehyde group, a group represented by Formula (u-r-1), a group represented by Formula (u-r-2), or a group represented by Formula (u-r-3).

In Formula (u-r-1), R⁰¹ and R⁰² each independently are a monovalent hydrocarbon group. The monovalent hydrocarbon group preferably has 1 to 20 carbon atoms, more preferably 1 to 10 carbon atoms, and further more preferably 1 to 5 carbon atoms.

Specific examples of the monovalent hydrocarbon group include a monovalent linear or branched alkyl group.

As the linear alkyl group, a methyl group, an ethyl group, a propyl group, a butyl group, and a pentyl group are preferable, and a methyl group is preferable.

Examples of the branched alkyl group include 1-methylethyl group, 1-methylpropyl group, 2-methylpropyl group, 1-methylbutyl group, 2-methylbutyl group, 3-methylbutyl group, 1-ethylbutyl group, 2-ethylbutyl group, 1-methylpentyl group, 2-methylpentyl group, 3-methylpentyl group, 4-methylpentyl group, and the like.

The monovalent linear or branched alkyl group may have a substituent. Examples of the substituent include a hydroxy group, a carbonyl group, an alkoxy group, a halogen atom, an aryl group, an alkenyl group, an alkynyl group, and the like.

In Formula (u-r-2), R⁰³ is a divalent hydrocarbon group. The divalent hydrocarbon group preferably has 1 to 20 carbon atoms, and more preferably 1 to 10 carbon atoms. Specific examples of the divalent hydrocarbon group include a linear or branched alkylene group.

Examples of the linear alkylene group include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], and the like.

Examples of the branched alkylene group include an alkylalkylene group encompassing an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, —C(CH₂CH₃)₂— or the like; an alkylethylene group such as —CH(CH₃)CH₂—, —CH(CH₃)CH(CH₃)—, —C(CH₃)₂CH₂—, —CH(CH₂CH₃)CH₂—, —C(CH₂CH₃)₂—CH₂— or the like; an alkyltrimethylene group such as —CH(CH₃)CH₂CH₂—, —CH₂CH(CH₃)CH₂— or the like; an alkyltetramethylene group such as —CH(CH₃)CH₂CH₂CH₂—, —CH₂CH(CH₃)CH₂CH₂— or the like; and the like.

In Formula (u-r-3), R⁰⁴ is a monovalent hydrocarbon group. Examples of the monovalent hydrocarbon group include those similar to the monovalent hydrocarbon group for R⁰¹ and R⁰² in Formula (u-r-1).

In Formula (u11-1), among these, Rp¹¹ in Formula is preferably an aldehyde group or a group represented by Formula (u-r-1), and more preferably an aldehyde group.

Specific examples of the structural unit (u11) are shown below.

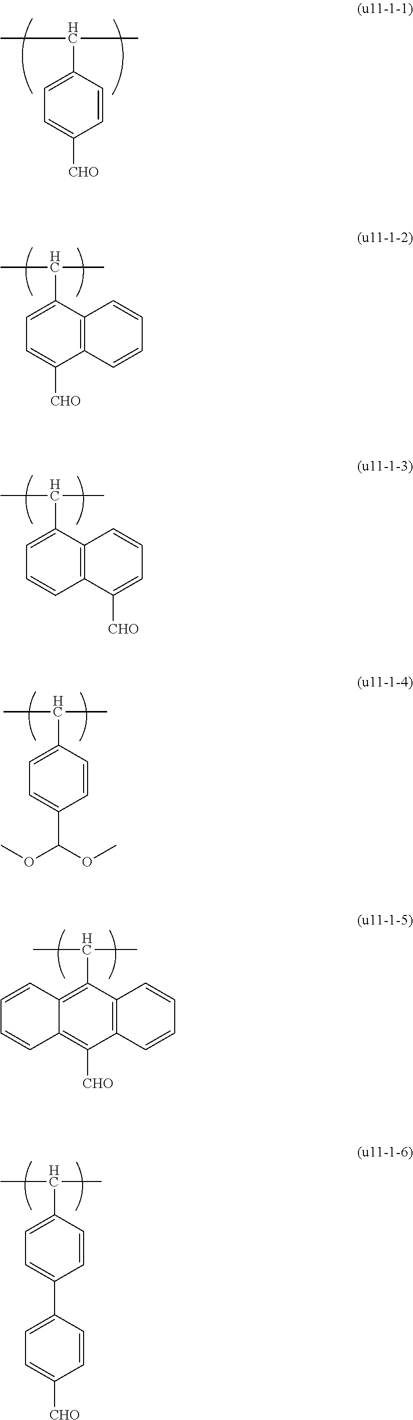

The structural unit (u11) of the resin (P1) may be one, or may be two or more.

A proportion of the structural unit (u11) in the resin (P1) is preferably 1 to 99 mol %, and more preferably 5 to 90 mol %, based on the total sum of all structural units constituting the resin (P1).

In a case where the proportion of the structural unit (u11) is equal to or more than the lower limit value of the preferable range, low outgassing property and crack resistance are further improved. In addition, in a case where the proportion of the structural unit (u11) is equal to or less than the upper limit value of the preferable range, sufficient etching resistance and heat resistance are obtained.

Other Structural Units

The resin (P1) may contain other structural units in addition to the structural unit (u11) stated above. Examples of the other structural units include a structural unit (u12) represented by General Formula (u12-1); a structural unit (u13) represented by General Formula (u13-1); and a structural unit (u14) represented by General Formula (u14-1).

Structural Unit (u12)

The structural unit (u12) is a structural unit represented by General Formula (u12-1).

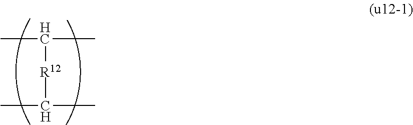

[In Formula (u12-1), R¹² is an aromatic hydrocarbon group which may have a substituent.]

In Formula (u12-1), R′² is an aromatic hydrocarbon group which may have a substituent, and examples thereof include the same ones as R¹¹ in Formula (u11-1) stated above.

Specific examples of the structural unit (u12) are shown below.

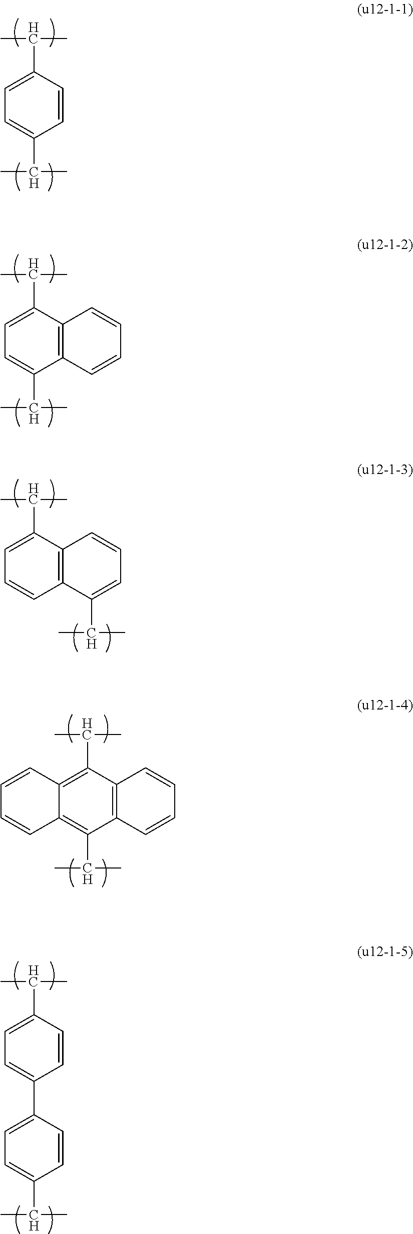

The structural unit (u12) of the resin (P1) may be one, or may be two or more.

A proportion of the structural unit (u12) in the resin (P1) is preferably 1 to 99 mol %, and more preferably 10 to 95 mol %, based on the total sum of all structural units constituting the resin (P1).

In a case where the proportion of the structural unit (u12) is equal to or more than the lower limit value of the preferable range, etching resistance and heat resistance are improved. Additionally, in a case where the proportion of the structural unit (u12) is equal to or less than the upper limit value of the preferable range, the structural unit (u12) can be easily balanced with other structural units.

Structural Unit (u13)

The structural unit (u13) is a structural unit represented by General Formula (u13-1).

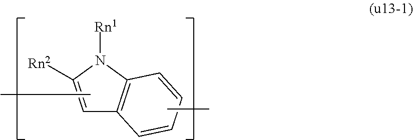

[In Formula (u13-1), Rn¹ and Rn² each independently are a hydrogen atom or a monovalent hydrocarbon group.]

Examples of the monovalent hydrocarbon group for Rn¹ and Rn² include a chain hydrocarbon group or a cyclic hydrocarbon group, or a hydrocarbon group combining a chain and a ring.

Examples of the chain hydrocarbon group include a linear alkyl group and a branched alkyl group. As the linear alkyl group, a methyl group, an ethyl group, a propyl group, a butyl group, and a pentyl group are preferable, and a methyl group is preferable.

Examples of the branched alkyl group include 1-methylethyl group, 1-methylpropyl group, 2-methylpropyl group, 1-methylbutyl group, 2-methylbutyl group, 3-methylbutyl group, 1-ethylbutyl group, 2-ethylbutyl group, 1-methylpentyl group, 2-methylpentyl group, 3-methylpentyl group, and 4-methylpentyl group.

The cyclic hydrocarbon group may be an alicyclic hydrocarbon group, or may be an aromatic hydrocarbon group.

The alicyclic hydrocarbon group may be either monocyclic or polycyclic.

Examples of the monocyclic alicyclic hydrocarbon group include cycloalkyl groups such as a cyclopropyl group, a cyclobutyl group, a cyclopentyl group, a cyclohexyl group, a methylcyclohexyl group, a dimethylcyclohexyl group, a cycloheptyl group, a cyclooctyl group, a cyclononyl group, and a cyclodecyl group.

Examples of the polycyclic alicyclic hydrocarbon group include a decahydronaphthyl group, an adamantyl group, a 2-alkyladamantan-2-yl group, a 1-(adamantan-1-yl) alkane-1-yl group, a norbomyl group, a methylnorbornyl group, an isobornyl group, and the like.

Examples of the aromatic hydrocarbon group include a phenyl group, a naphthyl group, an anthryl group, a p-methylphenyl group, a p-tert-butylphenyl group, a p-adamantylphenyl group, a tolyl group, a xylyl group, a cumenyl group, a mesityl group, a biphenyl group, a phenanthryl group, a 2,6-diethylphenyl group, a 2-methyl-6-ethylphenyl group, and the like.

Among these, Rn¹ in Formula (u13-1) is preferably a hydrogen atom or a linear alkyl group having 1 to 5 carbon atoms, and more preferably a hydrogen atom or a methyl group.

Among these, Rn² in Formula (u13-1) is preferably a hydrogen atom or an aromatic hydrocarbon group, and more preferably a hydrogen atom or a phenyl group.

Specific examples of the structural unit (u13) are shown below.

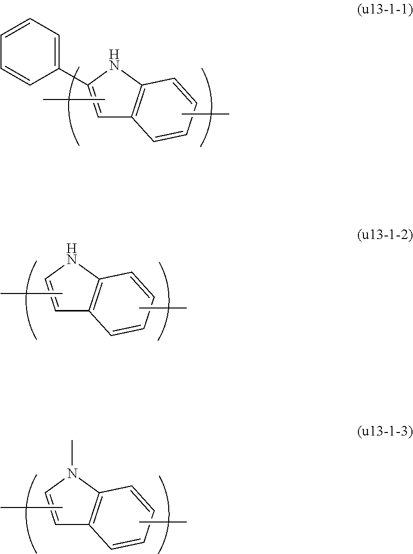

The structural unit (u13) of the resin (P1) may be one, or may be two or more.

A proportion of the structural unit (u13) in the resin (P1) is preferably 1 to 70 mol %, more preferably 10 to 65 mol %, and still more preferably 20 to 60 mol %, based on the total sum of all structural units constituting the resin (P1).

In a case where the proportion of the structural unit (u13) is at least the lower limit value of the preferable range, etching resistance and heat resistance are improved. In addition, stability over time is also improved.

On the other hand, in a case where the proportion of the structural unit (u13) is equal to or less than the upper limit value of the preferable range, the structural unit (u13) can be easily balanced with other structural units.

Structural Unit (u14)

The structural unit (u14) is a structural unit represented by General Formula (u14-1).

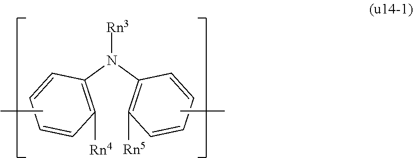

[In Formula (u14-1), Rn³ to Rn⁵ each independently are a hydrogen atom or a monovalent hydrocarbon group. Rn⁴ and Rn⁵ may be bonded to each other to form a condensed ring with the nitrogen atom in Formula.]

In Formula (u14-1), Rn³ to Rn⁵ each independently are a hydrogen atom or a monovalent hydrocarbon group. Examples of the monovalent hydrocarbon group include those similar to Rn¹ and Rn² in Formula (u13-1).

In Formula (u14-1), Rn⁴ and Rn⁵ may be bonded to each other to form a condensed ring together with the nitrogen atom in Formula. The condensed ring is preferably a carbazole ring.

Among these, Rn³ in Formula (u14-1) is preferably a hydrogen atom or an aromatic hydrocarbon group, and more preferably a hydrogen atom or a naphthyl group.

Among the, Rn⁴ and Rn⁵ in Formula (u14-1) each are a hydrogen atom, or preferably form a carbazole ring together with the nitrogen atom in Formula.

Specific examples of the structural unit (u14) are shown below.

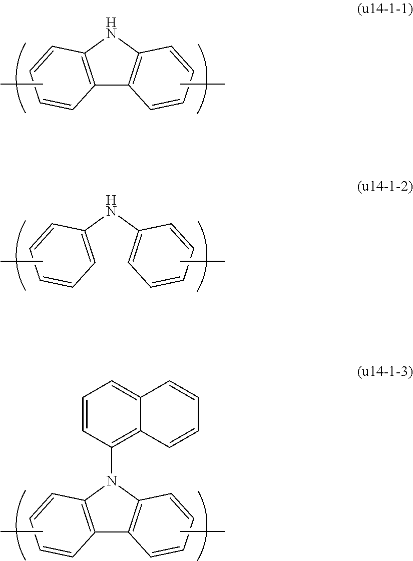

The structural unit (u14) of the resin (P1) may be one, or may be two or more.

A proportion of the structural unit (u14) in the resin (P1) is preferably 1 to 70 mol %, more preferably 10 to 65 mol %, and still more preferably 20 to 60 mol %, based on the total sum of all structural units constituting the resin (P1).

In a case where the proportion of the structural unit (u14) is at least the lower limit value of the preferable range, etching resistance and heat resistance are improved. In addition, stability over time is also improved.

On the other hand, in a case where the proportion of the structural unit (u14) is equal to or less than the upper limit value of the preferable range, the structural unit (u14) can be easily balanced with other structural units.

Examples of the resin (P1) include a resin having only the structural unit (u11); a resin having the structural unit (u11) and the structural unit (u12); a resin having the structural unit (u11), the structural unit (u12), and at least one structural unit selected from the group consisting of the structural unit (u13) and the structural unit (u14); and the like.

Examples of such a resin include a polymer (homopolymer) consisting only of a monomer from which the structural unit (u11) is derived; a copolymer of a monomer from which the structural unit (u11) is derived and a monomer from which the structural unit (u12) is derived; a copolymer of a monomer from which the structural unit (u11) is derived, a monomer from which the structural unit (u12) is derived, and at least one structural unit selected from the group consisting of a monomer from which the structural unit (u13) is derived and a monomer from which the structural unit (u14) is derived; and the like.

Among these, as the resin (P1), a copolymer of a monomer from which the structural unit (u11) is derived, a monomer from which the structural unit (u12) is derived, and a monomer from which at least one structural unit selected from the structural unit (u13) and the structural unit (u14) are derived is preferable.

A weight average molecular weight (Mw) (based on polystyrene conversion by gel permeation chromatography (GPC)) of the resin (P1) is not particularly limited, and is preferably about 1,000 to 500,000, and more preferably about 3,000 to 50,000. In a case where Mw of the resin (P1) is within the preferable range, etching resistance and heat resistance are preferable.

A polydispersity (Mw/Mn) of the resin (P1) is not particularly limited, and is preferably about 1.0 to 4.0, more preferably about 1.0 to 3.0, and particularly preferably about 1.0 to 2.5. Mn represents a number average molecular weight.

Specific examples of the resin (P1) are shown below.

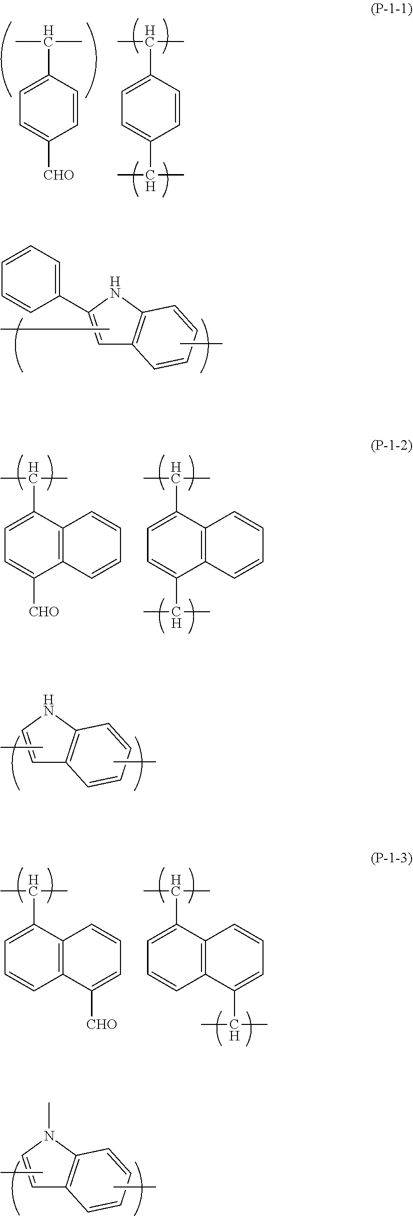

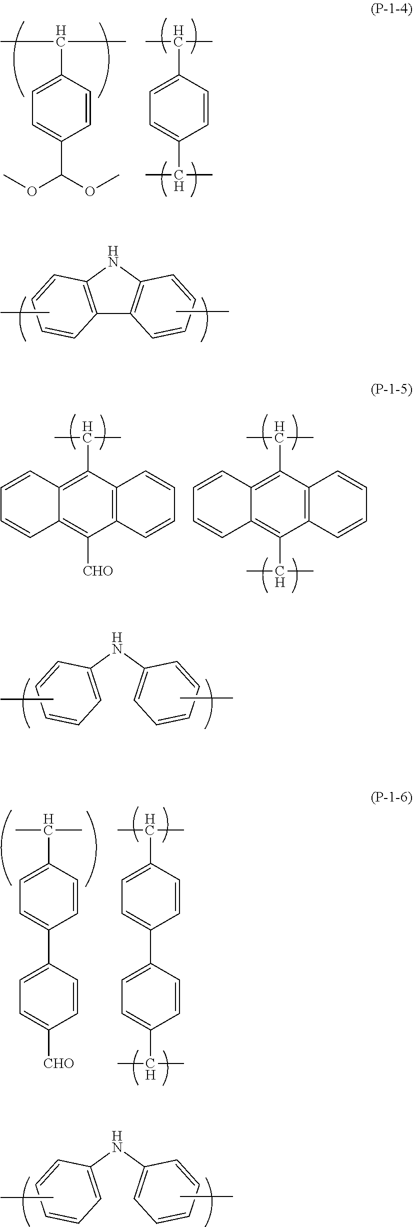

The resin (P1) can be prepared by, for example, condensing the monomer from which the structural unit (u11) is derived and the monomer from which the structural unit (u12) is derived, and a monomer from which the structural unit (u13) or the structural unit (u14) is derived in the presence of an acid catalyst. The acid catalyst is not particularly limited, and examples thereof include para-toluenesulfonic acid, hydrochloric acid, nitric acid, sulfuric acid, formic acid, oxalic acid, acetic acid, and the like.

The monomer from which the structural unit (u11) is derived and the monomer from which the structural unit (u12) is derived may be the same. An aldehyde compound can be typically used as the monomer from which the structural unit (u11) and the structural unit (u12) are derived. In the polymerization reaction, a resin having the structural unit (u11) and the structural unit (u12) can be manufactured by adjusting the reaction conditions and the addition amount of each monomer so that the aldehyde group remains in the manufactured resin.

For example, in a case where a copolymer of the structural unit (u11), the structural unit (u12), and the structural unit (u13) or the structural unit (u14) is manufactured, the copolymer is manufactured by condensing the addition amount of the monomer from which the structural unit (u11) and the structural unit (u12) are derived in an amount of equimolar or more with respect to the addition amount of the monomer from which the structural unit (u13) or the structural unit (u14) is derived.

On the other hand, in a case where the addition amount of the monomer from which the structural unit (u11) and the structural unit (u12) are derived is not equimolar but small (for example, in a case where the amount is about 1/3) with respect to the addition amount of the monomer from which the structural unit (u13) or the structural unit (u14) is derived, reaction proceeds and the obtained resin does not have an aldehyde group.

<<Resin (P2)>>

The resin (P2) is a resin containing an aromatic ring and a polar group. However, the resin (P1) stated above is excluded.

The aromatic ring contained in resin (P2) is not particularly limited as long as it is a cyclic conjugated system having 4n+2π electrons, and may be monocyclic or polycyclic. The aromatic ring has preferably 5 to 30 carbon atoms, more preferably 5 to 20 carbon atoms, and still more preferably 6 to 16 carbon atoms.

Specific examples of the aromatic ring include an aromatic hydrocarbon ring such as benzene, naphthalene, anthracene, and phenanthrene; an aromatic heterocyclic ring in which a part of carbon atoms constituting the aromatic hydrocarbon ring is substituted with hetero atoms; and the like. Examples of the hetero atom in the aromatic heterocyclic ring include an oxygen atom, a sulfur atom, a nitrogen atom, and the like. Specific examples of the aromatic heterocyclic ring include a pyridine ring, a thiophene ring, and the like.

The aromatic ring contained in the resin (P2) may be one, or may be two or more.

In a case where the resin (P2) has plural types of the structural units, at least one type of the structural unit contains the aromatic ring.

Examples of the polar group contained in the resin (P2) include a monovalent polar group such as a hydroxy group, a carboxy group, an amino group, a sulfo group, an alkoxy group, and an epoxy group (here, the same group as Rp¹¹ in Formula (u11-1) is excluded); a divalent polar group represented by —O—, —C(═O)—O—, —C(═O)—, —O—C(═O)—O—, —C(═O)—NH—, —NH—, —NH—C(═NH)— (H may be substituted with a substituent such as alkyl group and acyl group), —S—, —S(═O)₂—, —S(═O)₂—O—, —General Formula—Y²¹—O—Y22-, —Y²¹—O—, —Y²¹—C(═O)—O—, —C(═O)—O—Y²¹, —[Y²¹—C(═O)—O]m″-Y²²—, —Y²¹—O—C(═))—Y²²— or —Y²¹—S(═O)2-O—Y²²— [in Formula, Y²¹ and Y²² each independently are a divalent hydrocarbon group that may have a substituent, O is an oxygen atom, and m″ is an integer of 0 to 3], and the like. In addition, the polar group contained in the resin (P2) may be obtained by forming a cyclic structure formed by the divalent polar group and a hydrocarbon group.

The polar group contained in the resin (P2) may be one, or may be two or more.

In a case where the resin (P2) has plural types of the structural units, at least one type of structural unit contains the polar group.

Preferred examples of the resin (P2) include a resin including at least one structural unit selected from the group consisting of a structural unit (u21) represented by General Formula (u21-1), a structural unit (u22) represented by General Formula (u22-1), and a structural unit (u23) represented by General Formula (u23-1); and at least one structural unit selected from the group consisting of a structural unit (u24) represented by General Formula (u24-1) and a structural unit (u25) represented by General Formula (u25-1).

Structural Unit (u21)

The structural unit (u21) is a structural unit represented by General Formula (u21-1).

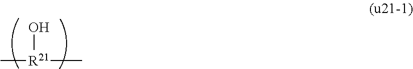

[In Formula (u21-1), R²¹ represents an aromatic hydrocarbon group which may have a substituent.]

In Formula (u21-1), the aromatic hydrocarbon group for R²¹ is a hydrocarbon group having at least one aromatic ring. The aromatic ring has the same content as described for the aromatic ring contained in the resin (P2). Examples of the substituent include a carbonyl group, an alkoxy group, a halogen atom, an alkyl group, an alkenyl group, an alkynyl group, and the like. The alkyl group, the alkenyl group, and the alkynyl group as the substituent preferably have 1 to 5 carbon atoms, and more preferably have 1 to 3 carbon atoms.

In Formula (u21-1), the aromatic hydrocarbon group for R²¹ is preferably a group having no substituent from a viewpoint of improving etching resistance.

Among these, the structural unit (u21) is preferably a structural unit from which a phenol compound is derived. The phenol compound is preferably a compound that can be condensed with an aldehyde to form a novolac resin or a resol resin. Examples of such a phenol compound include phenol; cresols such as m-cresol, p-cresol, o-cresol, and the like; xylenols such as 2,3-xylenol, 2,5-xylenol, 3,5-xylenol, 3,4-xylenol, and the like; alkylphenols such as m-ethylphenol, p-ethylphenol, o-ethylphenol, 2,3,5-trimethylphenol, 2,3,5-triethylphenol, 4-tert-butylphenol, 3-tert-butylphenol, 2-tert-butylphenol, 2-tert-butyl-4-methylphenol, 2-tert-butyl-5-methylphenol, and the like; alkoxyphenols such as p-methoxyphenol, m-methoxyphenol, p-ethoxyphenol, m-ethoxyphenol, p-propoxyphenol, m-propoxyphenol, and the like; isopropenylphenols such as o-isopropenylphenol, p-isopropenylphenol, 2-methyl-4-isopropenylphenol, 2-ethyl-4-isopropenylphenol, and the like; arylphenols such as phenyl phenol and the like; polyhydroxyphenols such as 4,4′-dihydroxybiphenyl, bisphenol A, resorcinol, hydroquinone, pyrogallol, 9,9-bis (4-hydroxy-3,5-dimethylphenyl) fluorene, 9,9-bis (4-hydroxy-3-methylphenyl) fluorene, 1,1-bis (4-hydroxy-3-methylphenyl) cyclohexane, and the like; and the like.

From a viewpoint of solubility in a solvent, the phenol compound preferably contains a phenol skeleton (benzene ring having at least one hydroxy group) but does not contain a bisnaphthol skeleton (a structure in which two naphthols are linked by a single bond or a divalent linking group).

Specific examples of the structural unit (u21) are shown below.

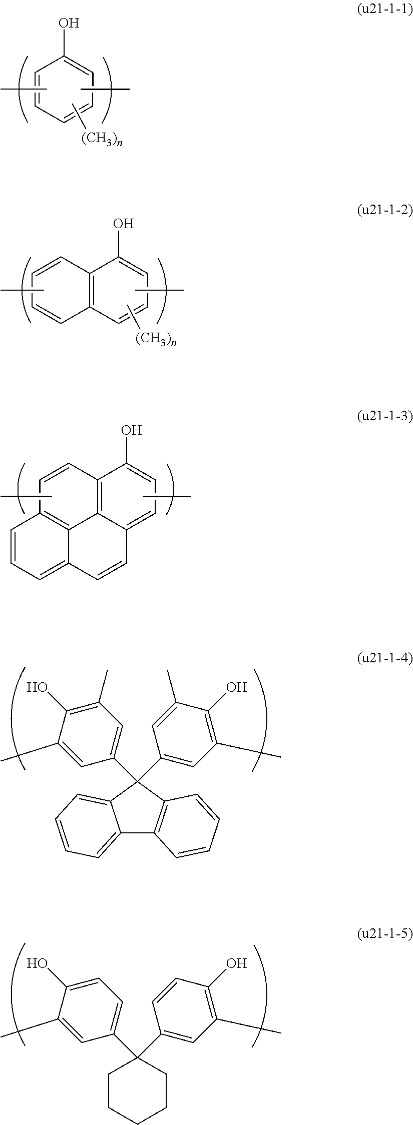

[In Formula (u21-1), n is an integer of 0 to 3.]

Structural Unit (u22) and Structural Unit (u23)

The structural unit (u22) is a structural unit represented by General Formula (u22-1).

The structural unit (u23) is a structural unit represented by General Formula (u23-1).

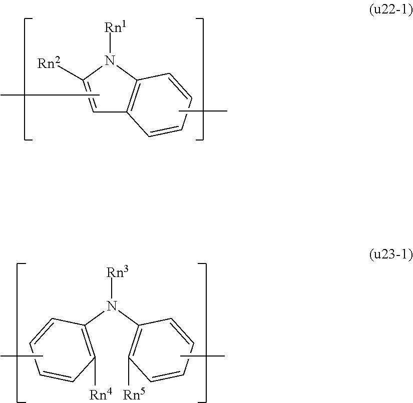

[In Formula (u22-1), Rn¹ and Rn² each independently are a hydrogen atom or a hydrocarbon group. In Formula (u23-1), Rn³ to Rn⁵ each independently are a hydrogen atom or a hydrocarbon group. Rn⁴ and Rn⁵ may be bonded to each other to form a condensed ring with the nitrogen atom in Formula.]

The structural unit (u22) is the same as the structural unit (u13) in the resin (P1) stated above.

The structural unit (u23) is the same as the structural unit (u14) in the resin (P1) stated above.

The structural unit (u21), the structural unit (u22), and the structural unit (u23) contained in the resin (P2) may be one type or two or more types, respectively.

A proportion (proportion of total sum) of the structural unit (u21), the structural unit (u22), and the structural unit (u23) in the resin (P2) is preferably 30 to 90 mol %, and more preferably 40 to 80 mol %, based on the total sum of all structural units constituting the resin (P2).

In a case where the proportion of the structural unit (u21) is at least the lower limit value of the preferable range, etching resistance and heat resistance are improved. Additionally, in a case where the proportion of the structural unit (u21) is equal to or less than the upper limit value of the preferable range, the structural unit (u21) can be easily balanced with other structural units.

Structural Unit (u24)

The structural unit (u24) is a structural unit represented by General Formula (u24-1).

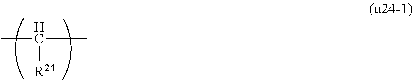

[In Formula (u24-1), R²⁴ is an aromatic hydrocarbon group that may have a substituent or a hydrogen atom.]

In Formula (u24-1), R²⁴ is an aromatic hydrocarbon group that may have a substituent or a hydrogen atom. The aromatic hydrocarbon group preferably has 6 to 25 carbon atoms, more preferably has 6 to 20 carbon atoms, and still more preferably has 6 to 15 carbon atoms.

Examples of the substituent include a carbonyl group, an alkoxy group, a halogen atom, an alkyl group, an alkenyl group, an alkynyl group, and the like. The alkyl group, the alkenyl group, and the alkynyl group in the substituent preferably have 1 to 5 carbon atoms, and more preferably have 1 to 3 carbon atoms. Preferred examples of the substituent include a linear or branched alkyl group having 1 to 5 carbon atoms.

The aromatic hydrocarbon group for R²⁴ is a hydrocarbon group having at least one aromatic ring. The aromatic ring has the same content as the aromatic ring contained in the resin (P2).

More specifically, the structural unit (u24) is preferably a structural unit from which an aldehyde compound is derived. Specific examples of the aldehyde compound include formaldehyde, paraformaldehyde, trioxane, furfural, benzaldehyde, terephthalaldehyde, phenylacetaldehyde, a-phenylpropyl aldehyde, β-phenylpropyl aldehyde, o-hydroxy benzaldehyde, m-hydroxy benzaldehyde, p-hydroxy benzaldehyde, o-methyl benzaldehyde, m-methyl benzaldehyde, p-methyl benzaldehyde, o-chlorobenzaldehyde, m-chlorobenzaldehyde, p-chlorobenzaldehyde, cinnamaldehyde, 4-isopropyl benzaldehyde, 4-isobutyl benzaldehyde, 4-phenyl benzaldehyde, and the like.

Specific examples of the structural unit (u24) are shown below.

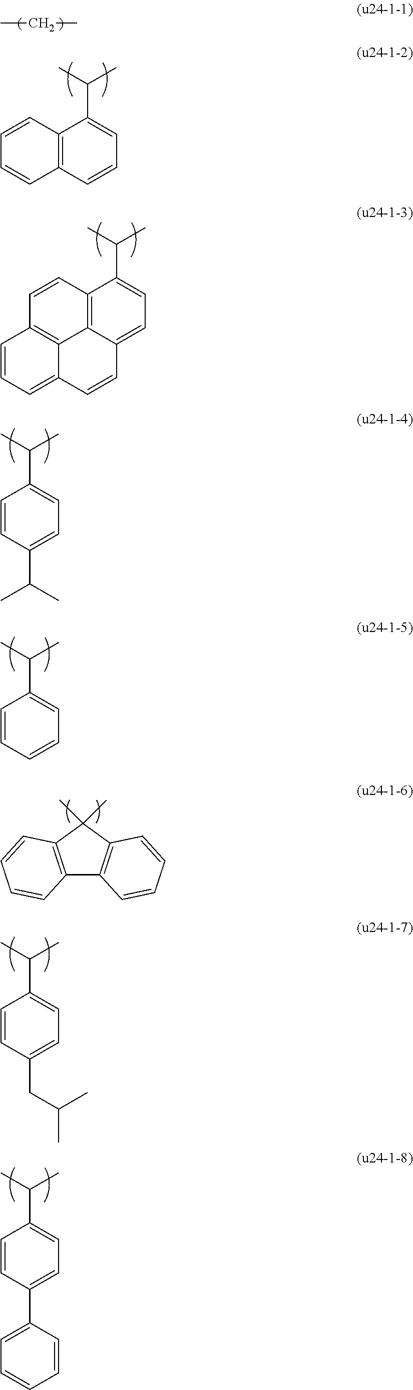

Structural Unit (u25)

The structural unit (u25) is a structural unit represented by General Formula (u25-1).

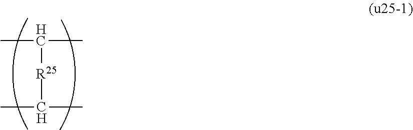

[In Formula (u25-1), R²⁵ represents an aromatic hydrocarbon group which may have a substituent.]

The structural unit (u25) is the same as the structural unit (u12) in the resin (P1) stated above.

The structural unit (u24) and the structural unit (u25) contained in the resin (P2) may be one type or two or more types, respectively.

A proportion (proportion of total sum) of the structural unit (u24) and the structural unit (u25) in the resin (P2) is preferably 30 to 70 mol %, based on the total sum of all structural units constituting the resin (P2).

Examples of the resin (P2) includes at least one structural unit selected from the group consisting of the structural unit (u21), the structural unit (u22), and the structural unit (u23), and at least one structural unit selected from the group consisting of the structural unit (u24) and the structural unit (u25).

Examples of such a resin preferably include a copolymer of a monomer for which the structural unit (u21) is derived and a monomer from which the structural unit (u24) is derived; a copolymer of a monomer from which the structural unit (u22) is derived and a monomer from which the structural unit (u24) is derived; a copolymer of a monomer from which the structural unit (u23) is derived and a monomer from which the structural unit (u24) is derived; a copolymer of a monomer from which the structural unit (u22) is derived and a monomer from which the structural unit (u25) is derived; and a copolymer of a monomer from which the structural unit (u21) is derived and a monomer from which the structural unit (u23) is derived, and a monomer from which the structural unit (u24) is derived.

A weight average molecular weight (Mw) (based on polystyrene conversion by gel permeation chromatography (GPC)) of the resin (P2) is not particularly limited, and is preferably about 1,000 to 100,000.

A polydispersity (Mw/Mn) of the resin (P2) is not particularly limited, and is preferably about 1 to 50. Mn represents a number average molecular weight.

The resin (P2) can be prepared by, for example, condensing the monomer from which the structural unit (u21) is derived and the monomer from which the structural unit (u24) is derived in the presence of an acid catalyst or an alkali catalyst. As the monomer from which the structural unit (u21) is derived, a phenol compound can be typically used. In addition, as a monomer from which the structural unit (u24) is derived, an aldehyde compound can be typically used. The acid catalyst is not particularly limited, and examples thereof include hydrochloric acid, nitric acid, sulfuric acid, formic acid, oxalic acid, acetic acid, and the like. Typically, in a case where a phenol compound and an aldehyde compound are condensed in the presence of an acid catalyst or an alkali catalyst, the compounding molar ratio of the aldehyde compound is generally smaller than that of the phenol compound (the compounding molar ratio is about 1/3).

The resin (P2) may be a commercially available novolac resin, a resol resin, and the like. Examples of the commercially available novolac resin include PR-53364, PR-53365, collectively manufactured by Sumitomo Bakelite, and the like.

Specific examples of the resin (P2) are shown below.

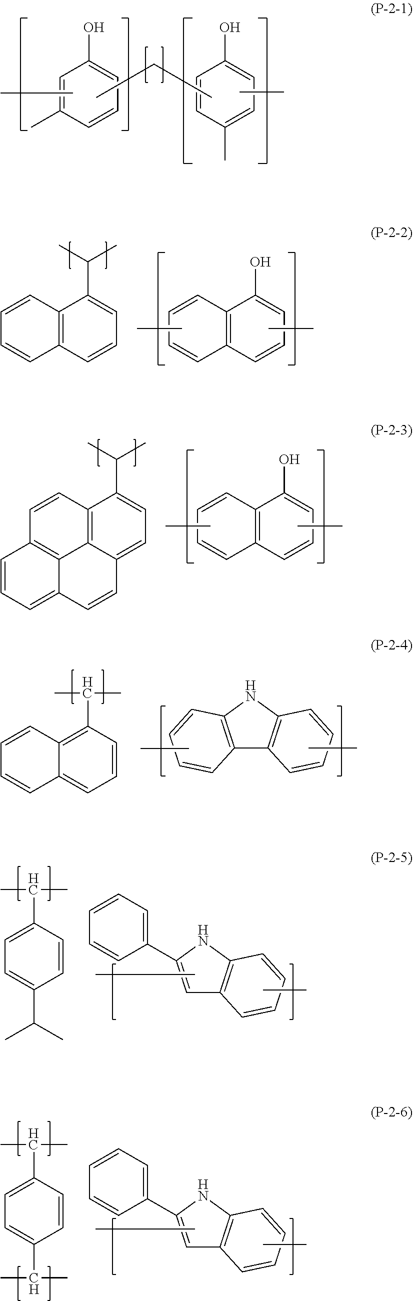

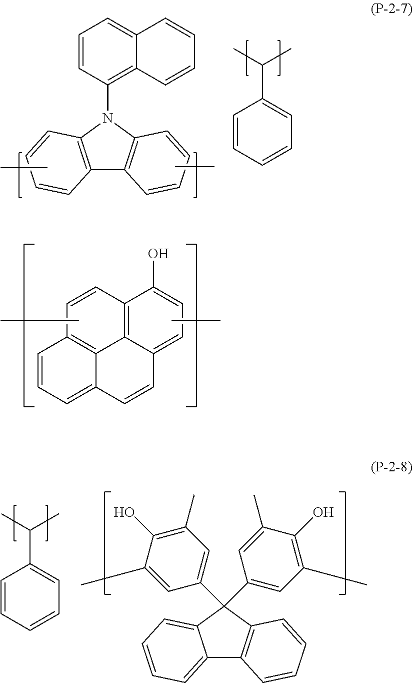

The mass ratio of the resin (P1) and the resin (P2), the resin (P2)/resin (P1) is preferably 1 to 15, more preferably 1.5 to 15, and further more preferably 2 to 12.

A proportion of the resin (P1) and the resin (P2) in the hard-mask forming composition is preferably 70 to 100 mass %, more preferably 80 to 100 mass %, still more preferably 90 to 100 mass %, particularly preferably 95 to 100 mass %, and most preferably 100 mass %, based on the total mass of all resins contained in the hard-mask forming composition. In a case where the proportion is at least the lower limit value of the preferable range stated above, etching resistance, low outgassing property, and crack resistance of the hard-mask forming composition are further improved.

<<Optional Components>>

The hard-mask forming composition of the present embodiment may contain other components in addition to the resin (P1) and the resin (P2) stated above. Examples of the other components include a heat acid generator, a surfactant, a crosslinking agent, a crosslinking acceleration catalyst, a photoacid generator, an absorbent, a rheology modifier, an adhesion aider, a solvent, and the like.

Heat Acid Generator

The hard-mask forming composition of the present embodiment preferably contains a heat acid generator (hereinafter, also referred to as “(T) component”).

Examples of the component (T) include perfluoroalkyl sulfonates (trifluoromethane sulfonate, perfluorobutane sulfonate, and the like) hexafluorophosphate, boron trifluoride salt, boron trifluoride ether complex, and the like.

Examples of preferable components (T) include a compound (T1) represented by General Formula (T-1) and consisting of a cationic part and an anionic part (hereinafter, also referred to as “component (T1)”), and a compound (T2) represented by General Formula (T-2) and consisting of a cationic part and an anionic part (hereinafter, also referred to as “component (T2)”).

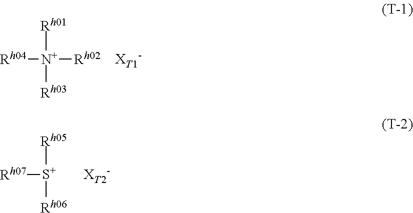

[In Formula (T-1), R^{h01} to R^{h04} each independently are a group selected from the group consisting of a hydrogen atom, an alkyl group having 1 to 20 carbon atoms, and an aryl group, and at least one of R^{h01} to R^{h04} is an aryl group. The alkyl group or aryl group may have a substituent. X_{T1}⁻ is a counter anion.

In Formula (T-2), R^{h05} to R^{h07} each independently are a group selected from the group consisting of an alkyl group having 1 to 20 carbon atoms and an aryl group, and at least one of R^{h05} to R^{h07} is an aryl group. The alkyl group or aryl group may have a substituent. X_{T2}⁻ is a counter anion.]

Regarding Anionic Part of Component (T1) and Component (T2)

Examples of X_{T1}⁻ in Formula (T-1) and X_{T2}⁻ in Formula (T-2) include a hexafluorophosphate anion, a perfluoroalkyl sulfonic acid anion (trifluoromethane sulfonate anion, perfluorobutane sulfonate anion), tetrakis (pentafluorophenyl) borate anion, and the like.

Among these, a perfluoroalkyl sulfonate anion is preferable, a trifluoromethane sulfonate anion or a perfluorobutane sulfonate anion is more preferable, and a trifluoromethane sulfonate anion is further preferable.

Regarding Cationic Part of Component (T1)

In Formula (T-1), the alkyl group for R^{h01} to R^{h04} is an alkyl group having 1 to 20 carbon atoms, preferably having 1 to 10 carbon atoms, more preferably having 1 to 5 carbon atoms, and is further more preferably a linear or branched alkyl group having 1 to 5 carbon atoms. Specific examples thereof include a methyl group, an ethyl group, a propyl group, an isopropyl group, an n-butyl group, an isobutyl group, a tert-butyl group, a pentyl group, an isopentyl group, a neopentyl group, and the like. Among these, a methyl group and an ethyl group are preferable.

The alkyl group for R^{h01} to R^{h04} may have a substituent. Examples of the substituent include an alkoxy group, a halogen atom, a halogenated alkyl group, a hydroxyl group, a carbonyl group, a nitro group, an amino group, a cyclic group, and the like.

The alkoxy group as the substituent of the alkyl group is preferably an alkoxy group having 1 to 5 carbon atoms, more preferably a methoxy group, an ethoxy group, an n-propoxy group, an iso-propoxy group, an n-butoxy group or a tert-butoxy group, and more preferably a methoxy group and an ethoxy group. Examples of the halogen atom as the substituent of the alkyl group include a fluorine atom, a chlorine atom, a bromine atom, an iodine atom, and the like, and the fluorine atom is preferable.

Examples of the halogenated alkyl group as the substituent of the alkyl group include an alkyl group having 1 to 5 carbon atoms, for example, a group in which a part or all of hydrogen atoms such as methyl group, ethyl group, propyl group, n-butyl group, and tert-butyl group is substituted with the halogen atom.

A carbonyl group as the substituent of the alkyl group is a group (>C═O) that substitutes a methylene group (—CH₂—) constituting the alkyl group.

Examples of the cyclic group as the substituent of the alkyl group include an aromatic hydrocarbon group and an alicyclic hydrocarbon group (which may be polycyclic or monocyclic). Examples of the aromatic hydrocarbon group here include the same as the aryl group for R^{h01} to R^{h04} to be stated later. In the alicyclic hydrocarbon group here, as the monocyclic alicyclic hydrocarbon group, a group obtained by removing one or more hydrogen atoms from a monocycloalkane is preferable. As the monocycloalkane, those having 3 to 6 carbon atoms are preferable, and specific examples thereof include cyclopentane, cyclohexane, and the like. In addition, as the polycyclic alicyclic hydrocarbon group, a group obtained by removing one or more hydrogen atoms from polycycloalkane is preferable, and as the polycycloalkane, those having 7 to 30 carbon atoms are preferable. Among these, as the polycycloalkane, a polycycloalkane having a polycyclic skeleton of a crosslinking ring system such as adamantane, norbornane, isobornane, tricyclodecane, and tetracyclododecane; and a polycycloalkane having a polycyclic skeleton of a condensed ring system such as a cyclic group having a steroid skeleton are more preferable.

In Formula (T-1), the aryl group for R^{h01} to R^{h04} is a hydrocarbon group having at least one aromatic ring.

The aromatic ring is not particularly limited as long as it is a cyclic conjugated system having 4n+2π electrons, and may be monocyclic or polycyclic. The aromatic ring preferably has 5 to 30 carbon atoms, more preferably has 5 to 20 carbon atoms, still more preferably has 6 to 15 carbon atoms, and particularly preferably has 6 to 12 carbon atoms.

Specific examples of the aromatic ring include an aromatic hydrocarbon ring such as benzene, naphthalene, anthracene, and phenanthrene; an aromatic heterocyclic ring in which a part of carbon atoms constituting the aromatic hydrocarbon ring is substituted with hetero atoms; and the like. Examples of the hetero atom in the aromatic heterocyclic ring include an oxygen atom, a sulfur atom, a nitrogen atom, and the like. Specific examples of the aromatic heterocyclic ring include a pyridine ring, a thiophene ring, and the like.

Specific examples of the aryl group for R^{h01} to R^{h04} include a group obtained by removing one hydrogen atom from the aromatic hydrocarbon ring or aromatic heterocyclic ring; a group obtained by removing one hydrogen atom from an aromatic compound (for example, biphenyl, fluorene, and the like) containing two or more aromatic rings; a group in which one hydrogen atom of the aromatic hydrocarbon ring or aromatic heterocyclic ring is substituted with an alkylene group (for example, arylalkyl group such as benzyl group, phenethyl group, 1-naphtylmethyl group, 2-naphtylmethyl group, 1-naphtylethyl group, 2-naphtylethyl group, and the like), and the like. An alkylene group to be bonded to the aromatic hydrocarbon ring or the aromatic heterocyclic ring preferably has 1 to 4 carbon atoms, more preferably has 1 to 2 carbon atoms, and particularly preferably has 1 carbon atom. Among these, a group obtained by removing one hydrogen atom from the aromatic hydrocarbon ring or aromatic heterocyclic ring, and a group in which one hydrogen atoms of the aromatic hydrocarbon ring or aromatic heterocyclic ring is substituted with an alkylene group are preferable, and a group obtained by removing one hydrogen atom from the aromatic hydrocarbon ring is substituted with an alkylene group and a group in which one hydrogen atom of the aromatic hydrocarbon ring is substituted with an alkylene group are further more preferable.

The aryl group for R^{h01} to R^{h04} may have a substituent. Examples of the substituent include an alkyl group, an alkoxy group, a halogen atom, a halogenated alkyl group, a hydroxyl group, a carbonyl group, a nitro group, an amino group, a cyclic group, an alkylcarbonyloxy group, and the like.

The alkyl group as the substituent of the aryl group is preferably an alkyl group having 1 to 5 carbon atoms, and preferably a methyl group, an ethyl group, a propyl group, an n-butyl group, and a tert-butyl group.

The description of the alkoxy group, the halogen atom, the halogenated alkyl group, the carbonyl group, and the cyclic group as the substituent of the aryl group is the same as the description of the alkoxy group, the halogen atom, the halogenated alkyl group, the carbonyl group, and the cyclic group as the substituent of the alkyl group stated above.

In the alkylcarbonyloxy group as a substituent of the aryl group, the alkyl part preferably has 1 to 5 carbon atoms, examples of the alkyl part include a methyl group, an ethyl group, a propyl group, an isopropyl group, and the like, and among these, a methyl group and an ethyl group are preferable, and a methyl group is more preferable.

However, in Formula (T1), at least one of R^{h01} to R^{h04} is an aryl group which may have a substituent.

Hereinafter, preferable cations as the cationic part of the component (T1) are shown below.

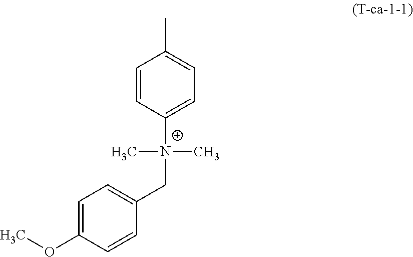

Regarding Cationic Part of Component (T2)

In Formula (T-2), the description of the alkyl group and the aryl group for R^{h05} to R^{h07} is the same as the description of the alkyl group and aryl group for R^{h01} to R^{h04} stated above, respectively.

However, in Formula (T-2), at least one of R^{h05} to R^{h07} is an aryl group which may have a substituent.

Hereinafter, preferable cations as the cationic part of the component (T2) are shown below.

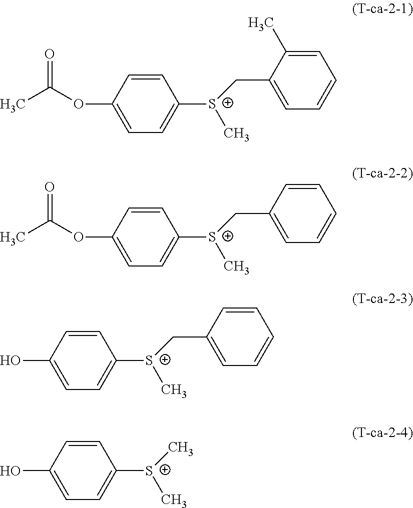

The component (T) contained in the hard-mask forming composition of the present embodiment may be one type, or may be two or more types.

Among these, the hard-mask forming composition of the present embodiment preferably contains the component (T1). As the component (T1), for example, a commercially available product having a trade name of TAG-2689 (manufactured by KING INDUSTRY) may be used.

In a case where the hard-mask forming composition of the present embodiment contains the component (T), a content of the component (T) is preferably 0.01 to 20 parts by mass, more preferably 0.1 to 10 parts by mass, and further more preferably 0.5 to 5 parts by mass, with respect to 100 parts by mass of the total amount of the resin (P1) and the resin (P2).

In a case where the content of the component (T) is within the preferable range, reactivity of the crosslinking reaction is further enhanced, and the low outgassing property and crack resistance are further enhanced.

Surfactant

The hard-mask forming composition of the present embodiment preferably further contains a surfactant.

Examples of the surfactant include a nonionic surfactant encompassing: polyoxyethylene alkyl ethers such as polyoxyethylene lauryl ether, polyoxyethylene stearyl ether, polyoxyethylene cetyl ether, polyoxyethylene oleyl ether or the like; polyoxyethylene alkyl allyl ethers such as polyoxyethylene octyl phenol ether, polyoxyethylene nonyl phenol ether or the like; polyoxyethylene-polyoxypropylene block copolymers; sorbitan fatty acid esters such as sorbitan monolaurate, sorbitan monopalmitate, sorbitan monostearate, sorbitan monooleate, sorbitan trioleate, sorbitan tristearate or the like; polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate or the like; fluorinated surfactants such as F-top [registered trademark] EF 301, EF 303, and EF 352 [collectively manufactured by Mitsubishi Materials Electronic Chemicals Co., Ltd. (formerly Tochem Products), product names], Megafac [registered trademark] F171, F173, R-30, and R-40 [collectively manufactured by DIC Corporation (formerly Dai Nippon Ink Co., Ltd.), product names], Fluorad FC430 and FC431 (collectively manufactured by Sumitomo 3M Co., Ltd., product names), Asahi Guard [registered trademark] AG710, Surflon [registered trademark] S-382, SC101, SC102, SC103, SC104, SC105, and SC106 (collectively manufactured by Asahi Glass Co., Ltd., product names), or the like; Organosiloxane Polymer KP341 (manufactured by Shin-Etsu Chemical Co., Ltd.); and the like.

The surfactant contained in the hard-mask forming composition of the present embodiment may be one type or two or more types.

Among these, the hard-mask forming composition of the present embodiment preferably contains a fluorinated surfactant.

In a case where the hard-mask forming composition of the present embodiment contains a surfactant, a content of the surfactant is preferably 0.01 to 10 parts by mass, more preferably 0.01 to 5 parts by mass, and further more preferably 0.05 to 1 parts by mass, with respect to 100 parts by mass of the total amount of the resin (P1) and the resin (P2).

In a case where the content of the surfactant is within the preferable range stated above, a film surface when applying the hard-mask forming composition is made uniform, and striations (application defects such as wavy and striped patterns) can be further prevented.

Crosslinking Agent

Examples of the crosslinking agent include an amino-based crosslinking agent such as glycoluril having a methylol group or an alkoxymethyl group; a melamine-based crosslinking agent; and the like. Specific examples include Nikalac (registered trademark) series (Nikalac MX270 and the like) manufactured by Sanwa Chemical Co., Ltd. A blending amount of the crosslinking agent component is preferably 1 to 50 parts by mass, and more preferably 1 to 40 parts by mass, based on 100 parts by mass of all resin components in the hard-mask forming composition. The crosslinking agent may be used alone, or two or more types thereof may be used in combination.

Crosslinking Acceleration Catalyst

Examples of the crosslinking acceleration catalyst include acidic compounds such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, and naphthalenecarboxylic acid, and the like. The crosslinking acceleration catalyst may be used alone, or two or more types thereof may be used in combination.

Photoacid Generator

Examples of the photoacid generator include onium salt photoacid generators such as bis (4-t-butylphenyl) iodonium trifluoromethanesulfonate, triphenylsulfonium trifluoromethanesulfonate or the like; halogen-containing compound photoacid generators such as phenyl-bis (trichloromethyl)-s-triazine or the like; sulfonic acid photoacid generators such as benzoin tosylate, N-hydroxysuccinimide trifluoromethanesulfonate or the like; and the like. A blending amount of the photoacid generator is preferably 0.2 to 10 parts by mass, more preferably 0.4 to 5 parts by mass, based on 100 parts by mass of all resin components in the hard-mask forming composition. The photoacid generator may be used alone, or two or more types may be used in combination.

Absorbent

Examples of the absorbent include commercially available absorbents listed in “Technology and Market for Industrial Dyes” (published by CMC) and “Dyes Handbook” (edited by the Society of Synthetic Organic Chemistry), for example, C. I. Disperse Yellow 1, 3, 4, 5, 7, 8, 13, 23, 31, 49, 50, 51, 54, 60, 64, 66, 68, 79, 82, 88, 90, 93, 102, 114 and 124; C. I. Disperse Orange 1, 5, 13, 25, 29, 30, 31, 44, 57, 72 and 73; C. I. Disperse Red 1, 5, 7, 13, 17, 19, 43, 50, 54, 58, 65, 72, 73, 88, 117, 137, 143, 199 and 210; C. I. Disperse Violet 43; C. I. Disperse Blue 96; C. I. Fluorescent Brightening Agent 112, 135 and 163; C. I. Solvent Orange 2 and 45; C. I. Solvent Red 1, 3, 8, 23, 24, 25, 27 and 49; C. I. Pigment Green 10; C. I. Pigment Brown 2; and the like. A blending amount of the absorbent is preferably 10 parts by mass or less, more preferably 5 parts by mass or less, based on 100 parts by mass of all resin components in the hard-mask forming composition. The absorbent may be used alone, or two or more types may be used in combination.

Rheology Modifier

Examples of the rheology modifier include phthalic acid derivatives such as dimethyl phthalate, diethyl phthalate, diisobutyl phthalate, dihexyl phthalate, butyl isodecyl phthalate or the like; adipic acid derivatives such as dinormal butyl adipate, diisobutyl adipate, diisooctyl adipate, octyl decyl adipate or the like; maleic acid derivatives such as dinormal butyl malate, diethyl malate, dinonyl malate or the like; oleic acid derivatives such as methyl oleate, butyl oleate, tetrahydrofurfuryl oleate, or the like; and stearic acid derivatives such as normal butyl stearate, glyceryl stearate, or the like. A blending amount of the rheology modifier is preferably less than 30 parts by mass, based on 100 parts by mass of all resin components in the hard-mask forming composition. The rheology modifier may be used alone, or two or more types may be used in combination.

Adhesion Aider

Examples of the adhesion aider include chlorosilanes such as m-trimethylchlorosilane, dimethylvinylchlorosilane, methyldiphenylchlorosilane, chloromethyldimethylchlorosilane, or the like; alkoxysilanes such as trimethylmethoxysilane, dimethyldiethoxysilane, methyldimethoxysilane, dimethylvinylethoxysilane, diphenyldimethoxysilane, phenyltriethoxysilane, or the like; silazanes such as hexamethyldisilazane, N, N′-bis(trimethylsilyl) urea, dimethyltrimethylsilylamine, trimethylsilylimidazole, or the like; silanes such as vinyltrichlorosilane, γ-chloropropyltrimethoxysilane, γ-aminopropyltriethoxysilane, γ-glycidoxypropyltrimethoxysilane, or the like; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, mercaptopyrimidine, or the like; urea such as 1,1-dimethylurea, 1,3-dimethylurea, or the like; thiourea compounds; and the like. A blending amount of the adhesion aider is preferably less than 5 parts by mass, and more preferably less than 2 parts by mass, based on 100 parts by mass of all resin components in the hard-mask forming composition. The adhesion aider may be used alone, or two or more types may be used in combination.

Solvent

The solvent is used to dissolve the resin (P1), the resin (P2), and the optional components.

Examples of the solvent include lactones such as γ-butyrolactone, or the like; ketones such as acetone, methyl ethyl ketone, cyclohexanone, methyl-n-pentyl ketone, methyl isopentyl ketone, 2-heptanone, or the like; polyhydric alcohols such as ethylene glycol, diethylene glycol, propylene glycol, dipropylene glycol, or the like; derivatives of polyhydric alcohols which include compounds having an ester bond such as ethylene glycol monoacetate, diethylene glycol monoacetate, propylene glycol monoacetate, or dipropylene glycol monoacetate, compounds having an ether bond such as monoalkyl ethers (including monomethyl ether, monoethyl ether, monopropyl ether and monobutyl ether) or monophenyl ether of the polyhydric alcohol or the compound having the ester bond, and the like [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, ethyl ethoxypropionate or the like; aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, mesitylene or the like; dimethyl sulfoxide (DMSO); and the like.

Among these, it is preferred to employ PGME, PGMEA, ethyl lactate, butyl lactate, γ-butyrolactone, cyclohexanone, mixed solvents of those and the like, from the viewpoint of further improving the leveling property.

The solvent may be used alone or be a mixed solvent of two or more types of solvents. Examples of the mixed solvent include a mixed solvent of PGME and γ-butyrolactone.

The amount of the solvent used is not particularly limited, and is appropriately set to a concentration applicable to a substrate or the like, depending on the thickness of a coating film thickness. For example, the solvent may be blended so that the resin component concentration in the hard-mask forming composition falls within a range of 1% to 50% by mass, and preferably a range of 15% to 35% by mass.

The hard-mask forming composition of the present embodiment contains a resin (P1) having a structural unit (u11) and a resin (P2) containing an aromatic ring and a polar group. Although the resin (P2) containing an aromatic ring and a polar group can improve the etching resistance, it is too rigid, so that the resin (P2) alone causes cracks in the formed hard mask layer. Therefore, by using together the resin (P1) having the structural unit (u11) containing an aldehyde group or the like having an effect as a crosslinking agent, high crack resistance can be realized while maintaining high etching resistance. In addition, since the resin (P1) has higher heat resistance than the low molecular weight crosslinking agent in the related art, outgassing can be reduced.

As described above, the hard-mask forming composition of the present embodiment has high etching resistance, and also has excellent low outgassing property and crack resistance.

<Method for Manufacturing Electronic Component>

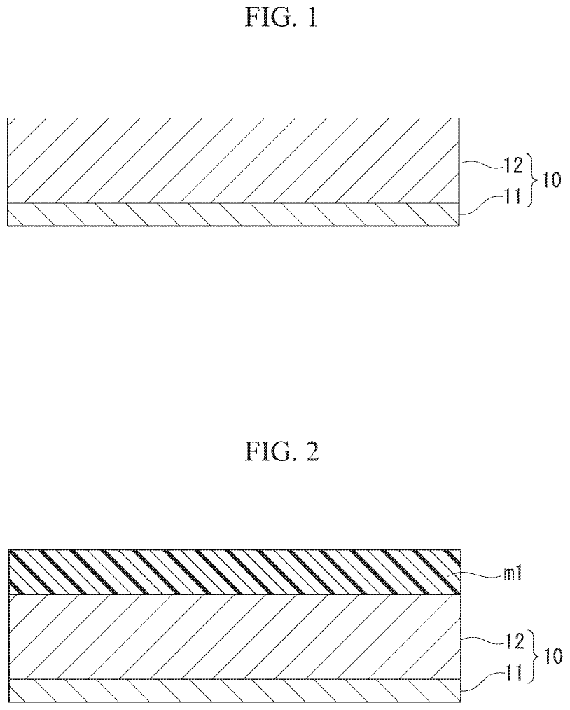

Specific examples of the method for manufacturing an electronic component according to second to fourth aspects of the present invention will be described with reference to FIGS. 1 to 8.

### First Embodiment

The method for manufacturing an electronic component of the present embodiment includes steps of:

forming a hard mask layer (m1) on a support using the hard-mask forming composition according to the first aspect stated above (hereinafter referred to as “step (i-i)”); and

processing the support using the hard mask layer (m1) as a mask (hereinafter, referred to as “step (i-a)”).

FIG. 1 shows a support 10 formed by a substrate 11 and a processing layer 12.

First, the hard mask layer (m1) is formed on the support 10 using the hard-mask forming composition according to the first aspect stated above (FIG. 2; step (i-i)).

[Step (i-i)]

Step (i-i) is a step of forming the hard mask layer (m1) on the support 10 using the hard-mask forming composition according to the first aspect stated above.

The substrate 11 is not particularly limited and a known substrate in the related art can be used. Examples thereof include a substrate for an electronic component, a substrate on which a predetermined wiring pattern is formed, and the like. More specifically, examples of the substrate include silicon wafers, metal substrates made of copper, chromium, iron, and aluminum, glass substrates, and the like. As a material of the wiring pattern, copper, aluminum, nickel, gold, and the like can be used.

Examples of the processing layer 12 include various low-k films such as films of Si, SiO₂, SiON, SiN, p-Si, α-Si, W, W—Si, Al, Cu and Al—Si, and stopper films thereof. The processing layer 12 usually has a thickness of 50 to 10,000 nm. In addition, in a case of performing deep processing, the thickness of the processing layer 13 may fall within a range of 1,000 to 10,000 nm.

The support 10 may not have the processing layer 12, but in a case of forming the processing layer 12, the substrate 11 and the processing layer 12 are usually made of different materials.

The hard mask layer (m1) is formed using the hard-mask forming composition according to the first aspect stated above. Specifically, the hard-mask forming composition according to the first aspect stated above is applied onto the support 10 by spin coating or the like. Subsequently, the hard mask layer (m1) is formed by baking and curing. Baking is typically performed within a range of 100° C. to 500° C., preferably within a range of 200° C. to 450° C., and more preferably within a range of 250° C. to 400° C. The baking temperature is adjusted to be equal to or less than the upper limit value of the range stated above, thus it is possible to suppress decrease in etching resistance due to the oxidation reaction of the resin. The baking temperature is adjusted to be at least the lower limit value of the range stated above, thus it is possible to suppress deterioration due to high temperature in the process described below. The baking time falls usually within a range of 10 to 600 seconds, preferably a range of 30 to 300 seconds, and more preferably a range of 50 to 200 seconds.

The thickness of the hard mask layer (m1) is not particularly limited, and can be appropriately set according to the thickness of the processing layer 12. The thickness of the hard mask layer (m1) may fall within a range of 30 to 20,000 nm. In addition, in a case of performing deep processing, the thickness of the hard mask layer (m1) is preferably 1,000 nm or more. In this case, the thickness of the hard mask layer (m1) falls within preferably a range of 1,000 to 20,000 nm, and more preferably a range of 1,000 to 15,000 nm.

[Step (i-a)]

Step (i-a) is a step of processing the support 10 using the hard mask layer (m1) as a mask. The support 10 can be processed by, for example, performing etching using the hard mask layer (m1) as a mask. A method of etching is not particularly limited, and common dry etching and the like can be used.

<<Second Embodiment>>

The method for manufacturing an electronic component of the present embodiment includes steps of:

forming a hard mask layer (m1) on a support using the hard-mask forming composition according to the first aspect stated above (hereinafter, referred to as “step (ii-i)”);

forming a hard mask layer (m2) made of an inorganic material on the hard mask layer (m1) (hereinafter, referred to as “step (ii-ii)”);

forming a resist film on the hard mask layer (m2) (hereinafter, referred to as “step (ii-iii)”);

exposing the resist film to light and developing the exposed resist film to form a resist pattern on the hard mask layer (m2) (hereinafter, referred to as “step (ii-iv)”);

etching the hard mask layer (m2) using the resist pattern as a mask to form an inorganic pattern (hereinafter, referred to as “step (ii-v)”);

etching the hard mask layer (m1) using the inorganic pattern as a mask to form a resin pattern (hereinafter, referred to as “step (ii-vi)”); and

processing the support using the resin pattern as a mask (hereinafter, referred to as “step (ii-vii)”).

FIG. 1 shows a support 10 formed by a substrate 11 and a processing layer 12.

First, the hard mask layer (m1) is formed on the support 10 using the hard-mask forming composition according to the first aspect stated above (FIG. 2; step (ii-i)).

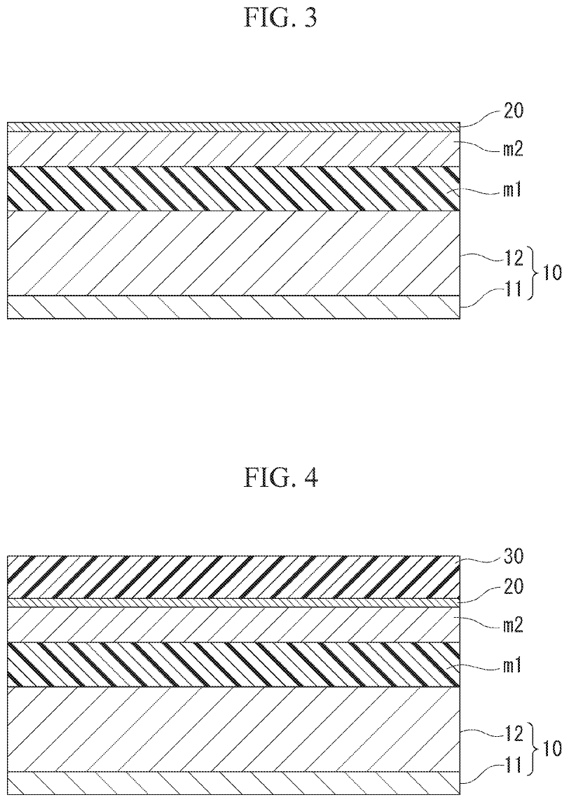

Subsequently, the hard mask layer (m2) made of an inorganic material is formed on the hard mask layer (m1) (FIG. 3; step (ii-ii)). In addition, an antireflective film (BARC layer) 20 is formed on the hard mask layer (m2) if needed.

Subsequently, a resist film 30 is formed on the hard mask layer (m2) using a resist composition (FIG. 4; step (ii-iii)).

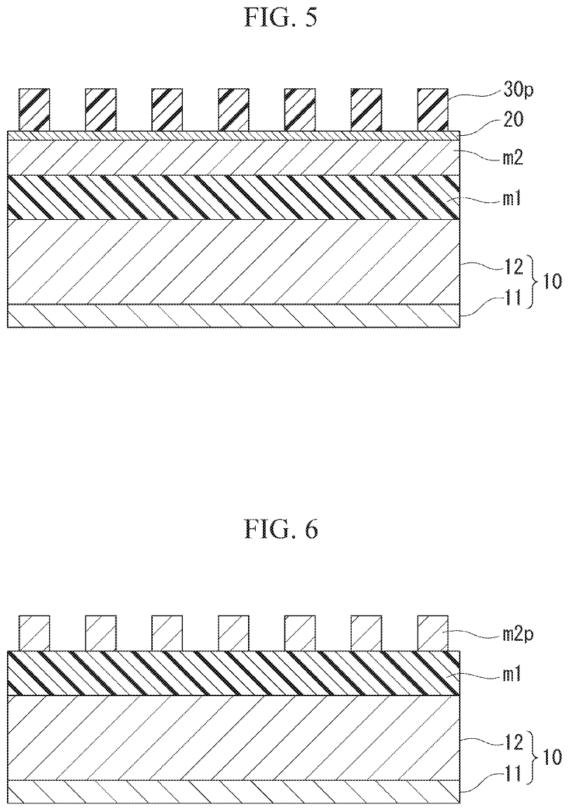

Subsequently, a resist pattern 30p is formed on the hard mask layer (m2) by exposing and developing the resist film (FIG. 5; step (ii-iv)).

Subsequently, the hard mask layer (m2) is etched with the resist pattern 30p as a mask to form an inorganic pattern (m2p) (FIG. 6; step (ii-v)).

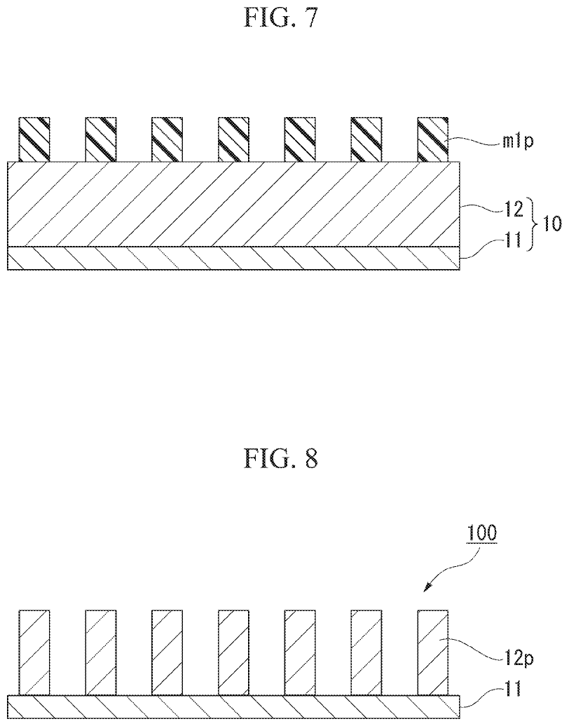

Subsequently, the hard mask layer (m1) is etched with the inorganic pattern (m2p) as a mask to form a resin pattern (m1p) (FIG. 7; step (ii-vi)).

Subsequently, the support 10 is processed with the resin pattern (m1p) as a mask to form a pattern 12p (FIG. 8; step (ii-vii)).

Thus, the electronic component 100 provided with the pattern 12p on the substrate 11 can be manufactured.

[Step (ii-i)]

The step (ii-i) is the same as the above-mentioned step (i-i).

[Step (ii-ii)]

Step (ii-ii) is a step of forming the hard mask layer (m2) made of an inorganic material on the hard mask layer (m1).

The inorganic material for forming the hard mask layer (m2) is not particularly limited, and known materials in the related art can be used. Examples of the inorganic material include a silicon oxide film (SiO₂ film), a silicon nitride film (Si₃N₄ film), a silicon oxynitride film (SiON film), and the like. Among these, a SiON film having a high effect as an antireflective film is preferable. The hard mask layer (m2) can be formed by a CVD method, an ALD method, and the like.

The thickness of the hard mask layer (m2) is, for example, about 5 to 200 nm, and preferably about 10 to 100 nm.

In a case where the CVD method or the ALD method is used to form the hard mask layer (m2), a temperature becomes high (about 400° C.), and thus the hard mask layer (m1) is required to have high temperature resistance. The hard-mask forming composition according to the first aspect stated above is excellent in heat resistance, and does not easily cause shrinkage even when exposed to a high temperature of about 400° C. Therefore, it can be suitably used in combination with the inorganic hard mask layer formed by the CVD method or the ALD method.

After forming the hard mask layer (m2), if needed, the antireflective film (BARC layer) 20 may be formed on the hard mask layer (m2). The BARC layer 20 may be an organic BARC, or may be an inorganic BARC. The BARC can be formed using known methods in the related art.

[Step (ii-iii)]

Step (ii-iii) is a step of forming the resist film 30 on the hard mask layer (m2) using a resist composition.

The resist composition is not particularly limited, and those proposed as a resist material suitable for a method using an exposure step can be generally used. The resist composition may be positive-tone or negative-tone. Examples of the resist composition include those containing a base component of which solubility in a developer changes due to action of the acid, and an acid generator component that generates the acid upon exposure.

The formation of the resist film 30 is not particularly limited, and a method generally used for forming the resist film 30 may be used. For example, the resist composition is applied by a spinner on the hard mask layer (m2) (in a case where the BARC layer 20 is formed, it is applied on the BARC layer 20 formed on the hard mask layer (m2)), and baked (post-apply baking (PAB)), for example, at a temperature of 80° C. to 150° C. for 40 to 120 seconds, and preferably for 60 to 90 seconds, thereby forming the resist film 30.

A thickness of the resist film 30 is not particularly limited, but it is generally about 30 to 500 nm.

[Step (ii-iv)]

Step (ii-iv) is a step of forming the resist pattern 30p on the hard mask layer (m2) by exposing and developing the resist film 30.

The resist film 30 can be exposed using an exposure apparatus such as an ArF exposure apparatus, a KrF exposure apparatus, an electron beam drawing apparatus, an EUV exposure apparatus, and the like. A wavelength used for exposure is not particularly limited, and exposure can be performed using ArF excimer laser, KrF excimer laser, F₂ excimer laser, EUV (extreme ultraviolet), VUV (vacuum ultraviolet), EB (electron beam), radiation such as X-ray and soft X-ray, and the like. The resist film 30 may be exposed by normal exposure (dry exposure) performed in an inert gas such as air and nitrogen, or by Liquid Immersion Lithography.

For example, the resist film 30 is selectively exposed by exposure through a photomask (mask pattern) on which a predetermined pattern is formed, by drawing with direct irradiation of the electron beam without a photomask, or the like. Subsequently, the resist film 30 is baked (post-exposure baking (PEB)), for example, at a temperature of 80° C. to 150° C. for 40 to 120 seconds, and for preferably 60 to 90 seconds.

Subsequently, the resist film 30 is developed. A developer used for the development can be appropriately selected from commonly used developers, depending on a type of the resist composition and a development method. For example, in a case of employing an alkali development process, an alkali developer is used, and in a case of employing a solvent development process, a developer (organic developer) containing an organic solvent is used.

Examples of the alkali developer used for development in the alkali development process include an aqueous solution of 0.1% to 10% by mass of tetramethylammonium hydroxide (TMAH).

Examples of the organic solvent contained in the organic developer used for development in the solvent development process include polar solvents such as a ketone solvent, an ester solvent, an alcohol solvent, a nitrile solvent, an amide solvent, an ether solvent, and the like; a hydrocarbon solvent; and the like.

The development process can be carried out by a known development method, such as a method of immersing the support in the developer for a fixed time (dipping); a method of raising the developer on a surface of the support by surface tension and standing still for a fixed time (paddling); a method of spraying the developer on the surface of the support (spraying); a method of continuously applying the developer while scanning the developer-coating nozzle at constant speed on the support rotating at constant speed (dynamic dispensing); or the like.

After the development process, the developed film is preferably rinsed. In a case of the alkali development process, the developed film is preferably rinsed using pure water, and in a case of the solvent development process, the developed film is preferably rinsed using a rinse solution containing an organic solvent.

Meanwhile, in a case of the solvent development process, after the development or rinsing, the developer or rinse solution adhering on the pattern may be removed with a supercritical fluid.

After the development or rinsing, the film is dried. In addition, the film may be baked (post baking) after the development if needed.

Therefore, the resist pattern 30p can be formed on the hard mask layer (m2).

[Step (ii-v)]

Step (ii-v) is a step of etching the hard mask layer (m2) with the resist pattern 30p as a mask to form the inorganic pattern (m2p).

A method of etching the hard mask layer (m2) is not particularly limited, and for example, common dry etching can be used. Examples of the etching method include chemical etching such as down flow etching, chemical dry etching, or the like; physical etching such as sputter etching, ion beam etching, or the like; and chemical-physical etching such as RIE (reactive ion etching), or the like.

For example, in parallel plate RIE, a multilayer laminate is placed in a chamber of an RIE apparatus, and necessary etching gas is introduced. When a high frequency voltage is applied to a holder of the multilayer laminate placed in parallel with an upper electrode in the chamber, the etching gas is made to plasma. Etching species including charged particles such as positive and negative ions or electrons, and neutral active species are present in the plasma. When these etching species are adsorbed to a lower resist layer, a chemical reaction occurs. Reaction products leave a surface and are exhausted to the outside, thereby performing etching.

Examples of the etching gas used for etching the hard mask layer (m2) include halogen-based gas. Examples of the halogen-based gas include hydrocarbon gas in which part or all of hydrogen atoms are substituted with halogen atoms such as fluorine atoms, chlorine atoms, or the like. In particular, those examples include fluorinated carbon-based gas such as tetrafluoromethane (CF₄) gas or trifluoromethane (CHF₃) gas; carbon chloride-based gas such as tetrachloromethane (CCl₄) gas; and the like.

[Step (ii-vi)]

Step (ii-vi) is a step of etching the hard mask layer (m1) with the inorganic pattern (m2p) as a mask to form the resin pattern (m1p).

A method of etching is not particularly limited, and common dry etching can be employed the same as in step (ii-vi). Examples of the etching gas used for etching the hard mask layer (m1) include oxygen gas, sulfur dioxide gas, halogen-based gas, and the like. For example, oxygen plasma etching using oxygen gas as the etching gas and the like are preferable.

[Step (ii-vii)]

Step (ii-vii) is a step of processing the support 10 using the resin pattern (m1p) as a mask.

The support 10 can be processed by, for example, etching the processing layer 12 with the resin pattern (m1p) as a mask. A method of etching is not particularly limited, and common dry etching can be employed the same as in step (ii-vi). Examples of the etching gas used for etching the processing layer 12 include halogen-based gas.

In the method for manufacturing an electronic component according to the present embodiment, the hard mask layer (m1) can be thickened (1 μm or more) since the hard mask layer (m1) is formed using the hard-mask forming composition according to the first aspect stated above. Accordingly, the resin pattern formed from the hard mask layer (m1) can be suitably used as a mask for deep processing.

The method for manufacturing an electronic component by the three-layer resist method has been described above, but the electronic component may be manufactured by the two-layer resist method. In that case, the resist film 30, instead of the hard mask layer (m2), is formed on the hard mask layer (m1).

The resist film 30 is exposed and developed to form the resist pattern 30p on the hard mask layer (m1) in the same manner as in step (iv).

Subsequently, the hard mask layer (m1) is etched with the resist pattern 30p as a mask to form the resin pattern (m1p) in the same manner as in step (vi).

After that, the support 10 is processed with the resin pattern (m1p) as a mask to form the pattern 12p in the same manner as in step (vii).

Thus, the electronic component can also be manufactured by the two-layer resist method.

Therefore, the present invention also provides the method for manufacturing an electronic component, including steps of:

forming the hard mask layer (m1) on the support using the hard-mask forming composition according to the first aspect stated above;

forming the resist film on the hard mask layer (m1);

exposing the resist film to light and developing the exposed resist film to form a resist pattern on the hard mask layer (m1)

etching the hard mask layer (m1) with the resist pattern as a mask to form the resin pattern; and

processing the support using the resin pattern as a mask.

### Third Embodiment

The method for manufacturing an electronic component of the present embodiment includes steps of:

forming a hard mask layer (m1) on a support using the hard-mask forming composition according to the first aspect stated above (hereinafter, referred to as “step (iii-i)”);

forming an inorganic pattern made of an inorganic material on the hard mask layer (m1) (hereinafter, referred to as “step (iii-v)”);

etching the hard mask layer (m1) with the inorganic pattern as a mask to form a resin pattern (hereinafter, referred to as “step (iii-vi)”), and processing the support using the resin pattern as a mask (hereinafter, referred to as “step (iii-vii)”).

The method for manufacturing an electronic component according to the fourth aspect is the same as the method for manufacturing an electronic component according to the third aspect, except that the inorganic pattern made of the inorganic material is formed directly on the hard mask layer (m1) without forming the resist film.

Hereinafter, a specific example of the method for manufacturing an electronic component according to the present embodiment will be described with reference to FIGS. 1, 2, and 6 to 8. However, the manufacturing method according to the present embodiment is not limited thereto.

First, the hard mask layer (m1) is formed on the support 10 using the hard-mask forming composition according to the first aspect stated above (FIGS. 1 and 2; step (iii-i)). This step is the same as the above-mentioned step (ii-i).

Subsequently, the inorganic pattern (m2p) made of the inorganic material is formed on the hard mask layer (m1) (FIG. 6; step (iii-v)). As the inorganic material for forming the inorganic pattern (m2p), the same inorganic material as exemplified in step (ii-ii), a resist composition containing the inorganic material, and the like can be employed. A method for forming the inorganic pattern (m2p) is not particularly limited, and known methods in the related art can be used. For example, the inorganic pattern (m2p) is formed on the hard mask layer (m1) by forming an inorganic resist film on the hard mask layer (m1) using a resist composition containing an inorganic material, and exposing and developing such a film.

Subsequently, the hard mask layer (m1) is etched with the inorganic pattern (m2p) as a mask to form the resin pattern (m1p) (FIG. 7; step (iii-vi)). This step is the same as the above step (ii-vi).

Subsequently, the support 10 is processed with the resin pattern (m1p) as a mask to form a pattern 12p (FIG. 8; step (iii-vii)). This step is the same as the above-mentioned step (ii-vii).

The electronic component 100 provided with the pattern 12p on the substrate 11 can also be manufactured in this manner.

In the method for manufacturing an electronic component of each of the embodiments described above, the hard mask layer (m1) is formed using the hard-mask forming composition according to the first aspect stated above, and thus it is possible to manufacture an electronic component having low outgassing property and excellent crack resistance with high quality and stability.

The present invention is not limited to each of the embodiments described above, various modifications can be made within the scope shown in claims, and embodiments obtained by suitably combining technical means disclosed in different embodiments are also included in the technical scope of the present invention.

### EXAMPLES

Hereinafter, the present invention will be described in more detail referring to examples. However, the present invention is not limited to these examples.

### Production Example of Resin (P1)

<<Resin (P-1-1)>>

In a three-necked flask connected to a thermometer, a reflux tube and a nitrogen inlet tube, 20.00 g (103.94 mmol) of phenylindole, 13.88 g (103.94 mmol) of terephthalaldehyde, and 93.86 g of y-butyrolactone were dissolved, 1.97 g of 20% y-butyrolactone solution of para-toluenesulfonic acid was added to the resultant mixture, and the mixture was heated and stirred at the reaction temperature of 105° C. for 5 hours. After that, the reaction solution was cooled to room temperature.

The obtained reaction solution was dropwise added to excess amount of methanol (MeOH) to precipitate a polymer. The precipitated brown powder was washed with excess amount of methanol and dried to obtain 127.62 g (81.5% yield) of a resin (P-1-1).

For the resin (P-1-1), a weight average molecular weight (Mw) of standard polystyrene conversion calculated by GPC measurement was 7,400, and the polydispersity (Mw/Mn) was 2.67. The copolymerization composition ratio (ratio (molar ratio) of each structural unit in the structural formula) obtained by ¹³C-NMR was (1/m)/n=(50)/50. The resin (P-1-1) was confirmed to have an aldehyde group by 1H-NMR and 13C-NMR.

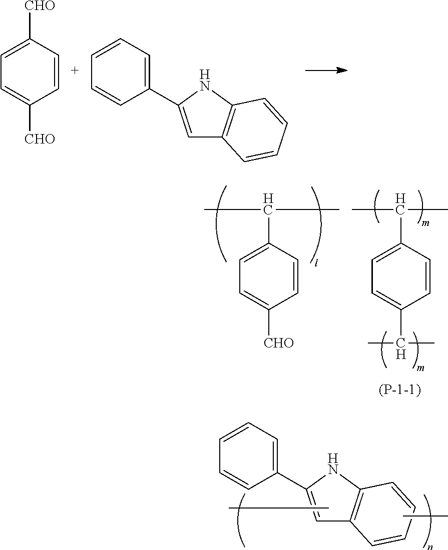

Resins (P-1-2) to (P-1-7) having the composition ratios shown in Table 1 were produced by the same method. For the obtained resin, the copolymerization composition ratio (ratio (molar ratio) of each structural unit of the resin) obtained by ¹³C-NMR, and the weight average molecular weight (Mw) of standard polystyrene conversion calculated by GPC measurement and the polydispersity (Mw/Mn) were also shown in Table 1.

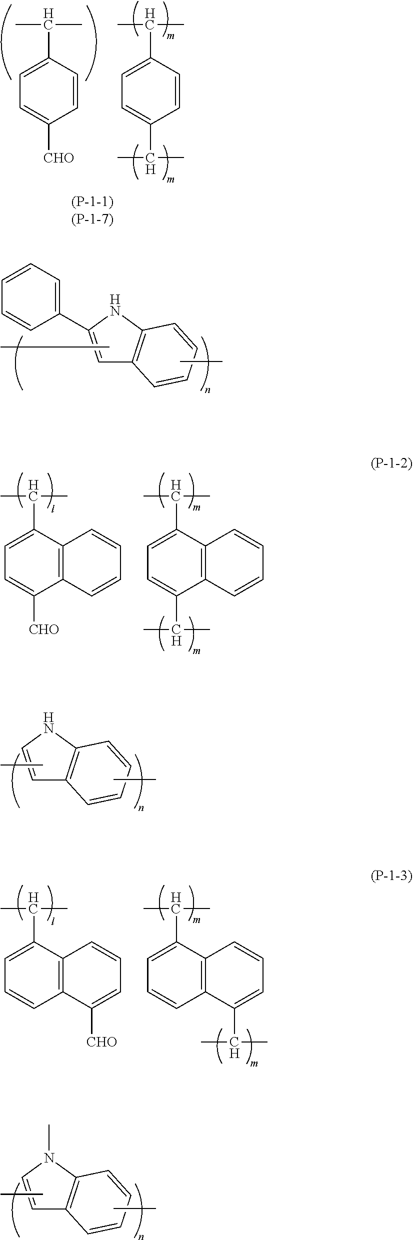

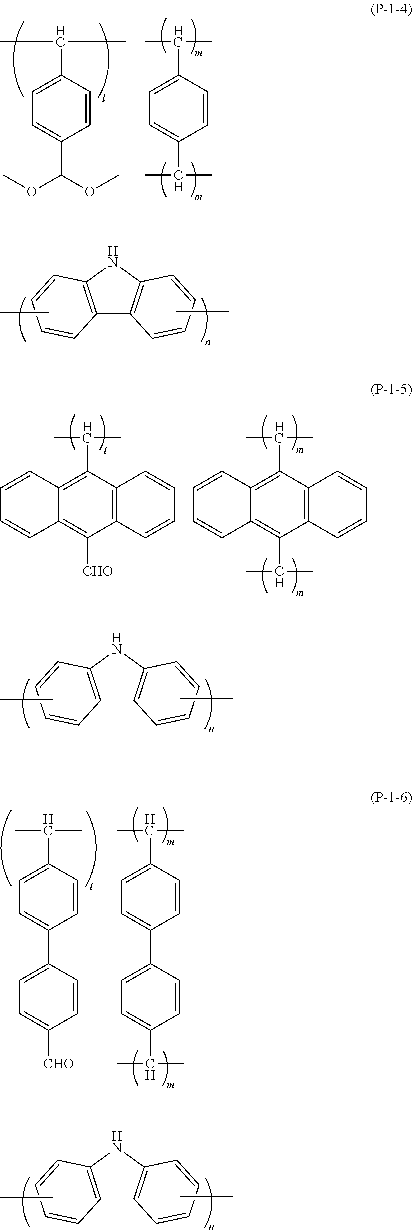

### Production Example of Resin (P2)

<<Resin (P-2-1)>>

Addition condensation of m-cresol, p-cresol, and formaldehyde was carried out in the presence of an acid catalyst by a conventional method to obtain the following resin (P-2-1). For the resin (P-2-1), a weight average molecular weight (Mw) of standard polystyrene conversion calculated by GPC measurement was 40,000, and the polydispersity (Mw/Mn) was 26.0.

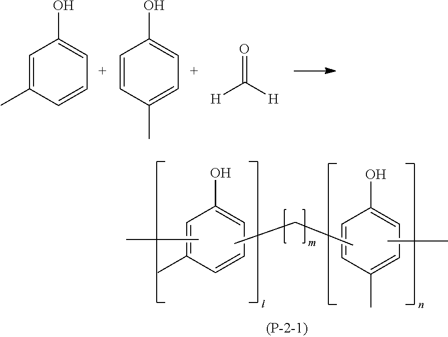

Resins (P-2-1) to (P-2-8) having the composition ratios shown in Table 1 were produced by the same method. For the obtained resin, the copolymerization composition ratio (ratio (molar ratio) of each structural unit of the resin) of the resin obtained by ¹³C-NMR, the weight average molecular weight (Mw) of standard polystyrene conversion calculated by GPC measurement, and the polydispersity (Mw/Mn) were also shown in Table 1.

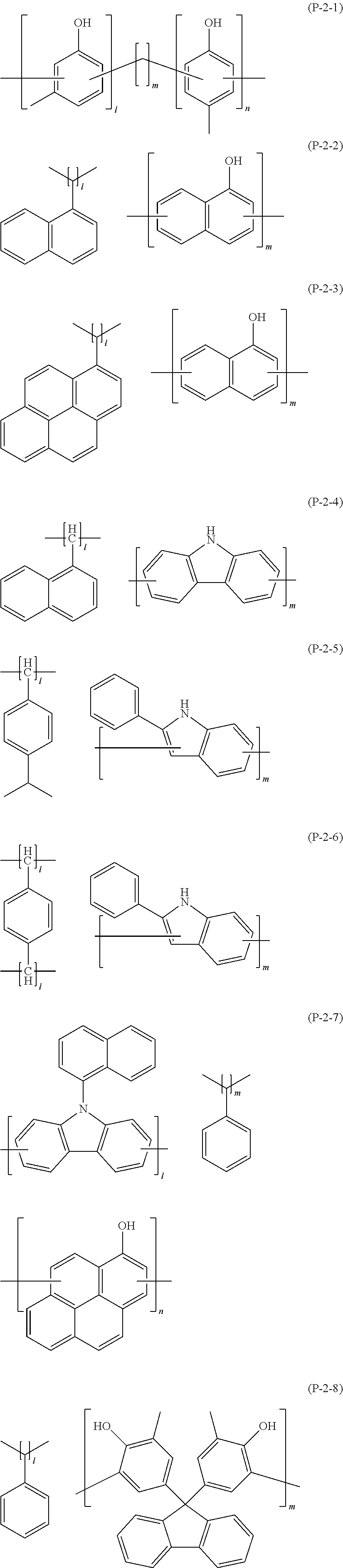

TABLE 1

| | | Copolymerization | Weight average | |
|---|---|---|---|---|
| | | composition ratio | molecular | Polydispersity |
| | Resin | (molar ratio) of resin | weight (Mw) | (Mw/Mn) |
| Production Example 1 | (P-1-1) | (l/m)/n = (50)/50 | 7,400 | 2.67 |
| Production Example 2 | (P-1-2) | (l/m)/n = (50)/50 | 6,800 | 2.48 |
| Production Example 3 | (P-1-3) | (l/m)/n = (50)/50 | 6,700 | 2.32 |
| Production Example 4 | (P-1-4) | (l/m)/n = (50)/50 | 15,600 | 3.66 |
| Production Example 5 | (P-1-5) | (l/m)/n = (70)/30 | 1,260 | 1.31 |
| Production Example 6 | (P-1-6) | (l/m)/n = (70)/30 | 2,240 | 1.56 |
| Production Example 7 | (P-1-7) | (l/m)/n = (50)/50 | 38,500 | 5.61 |
| Production Example 8 | (P-2-1) | l/m/n = 30/50/20 | 40,000 | 26.0 |
| Production Example 9 | (P-2-2) | l/m = 50/50 | 4,000 | 1.85 |
| Production Example 10 | (P-2-3) | l/m = 50/50 | 1,250 | 1.25 |
| Production Example 11 | (P-2-4) | l/m = 50/50 | 2,400 | 1.56 |
| Production Example 12 | (P-2-5) | l/m = 50/50 | 3,300 | 1.69 |
| Production Example 13 | (P-2-6) | l/m = 25/75 | 6,400 | 1.86 |
| Production Example 14 | (P-2-7) | l/m/ = 5/50/45 | 4,400 | 2.10 |
| Production Example 15 | (P-2-8) | l/m = 50/50 | 5,500 | 2.28 |

### Examples 1 to 15 and Comparative Examples 1 to 4

<Preparation of Hard-Mask Forming Composition>

Components listed in Tables 2 and 3 were mixed together and dissolved to prepare hard-mask forming compositions of each example.

TABLE 2

| | | | Thermal acid | | |
|---|---|---|---|---|---|
| | Resin component | | generator | Surfactant | Solvent |
| Example 1 | (P1)-1 | (P2)-1 | (T)-1 | (A)-1 | (S)-1 |
| | [17] | [83] | [1.67] | [0.083] | [583] |
| Example 2 | (P1)-1 | (P2)-2 | (T)-1 | (A)-1 | (S)-1 |
| | [23] | [77] | [1.54] | [0.077] | [346] |
| Example 3 | (P1)-1 | (P2)-3 | (T)-1 | (A)-1 | (S)-1 |
| | [33] | [67] | [1.33] | [0.067] | [300] |
| Example 4 | (P1)-1 | (P2)-4 | (T)-1 | (A)-1 | (S)-1 |
| | [17] | [83] | [1.67] | [0.083] | [375] |
| Example 5 | (P1)-1 | (P2)-5 | (T)-1 | (A)-1 | (S)-1 |
| | [9] | [91] | [1.82] | [0.091] | [382] |
| Example 6 | (P1)-1 | (P2)-6 | (T)-1 | (A)-1 | (S)-1 |
| | [17] | [83] | [1.67] | [0.083] | [350] |
| Example 7 | (P1)-1 | (P2)-7 | (T)-1 | (A)-1 | (S)-1 |
| | [17] | [83] | [1.67] | [0.083] | [375] |
| Example 8 | (P1)-1 | (P2)-8 | (T)-1 | (A)-1 | (S)-1 |
| | [17] | [83] | [1.67] | [0.083] | [375] |
| Example 9 | (P1)-2 | (P2)-7 | (T)-1 | (A)-1 | (S)-1 |
| | [17] | [83] | [1.67] | [0.083] | [375] |
| Example 10 | (P1)-3 | (P2)-7 | (T)-1 | (A)-1 | (S)-1 |
| | [17] | [83] | [1.67] | [0.083] | [375] |
| Example 11 | (P1)-4 | (P2)-7 | (T)-1 | (A)-1 | (S)-1 |
| | [17] | [83] | [1.67] | [0.083] | [375] |
| Example 12 | (P1)-5 | (P2)-7 | (T)-1 | (A)-1 | (S)-1 |
| | [17] | [83] | [1.67] | [0.083] | [375] |
| Example 13 | (P1)-6 | (P2)-7 | (T)-1 | (A)-1 | (S)-1 |
| | [17] | [83] | [1.67] | [0.083] | [375] |
| Example 14 | (P1)-7 | (P2)-7 | (T)-1 | (A)-1 | (S)-1 |
| | [17] | [83] | [1.67] | [0.083] | [600] |
| Example 15 | (P1)-1 | (P2)-7 | (T)-1 | (A)-1 | (S)-2 |
| | [17] | [83] | [1.67] | [0.083] | [375] |

TABLE 3

| | Resin | | Crosslin- | Thermal acid | Surfac- | Sol- |
|---|---|---|---|---|---|---|
| | component | | king agent | generator | tant | vent |
| Comparative | (P1)-1 | (P)-A | — | (T)-1 | (A)-1 | (S)-1 |
| Example 1 | [17] | [83] | | [1.67] | [0.083] | [375] |
| Comparative | — | (P2)-7 | (C)-1 | (T)-1 | (A)-1 | (S)-1 |
| Example 2 | | [100] | [30] | [2.00] | [0.100] | [450] |
| Comparative | (P1)-1 | — | (C)-1 | (T)-1 | (A)-1 | (S)-1 |
| Example 3 | [100] | | [20] | [2.00] | [0.100] | [450] |
| Comparative | (P1)-1 | — | — | (T)-1 | (A)-1 | (S)-1 |
| Example 4 | [100] | | | [2.00] | [0.100] | [440] |

Each abbreviation in Tables 2 and 3 is defined as follows. The numerical values in [ ] are blending amounts (parts by mass).

(P1)-1 to (P1)-7: the resins (P-1-1) to (P-1-7).

(P2)-1 to (P2)-8: the resins (P-2-1) to (P-2-8).

(P)-A: A polymer compound represented by the following chemical formula (P-A). The weight average molecular weight (Mw) of the standard polystyrene conversion obtained by GPC measurement was 94,100, and the polydispersity (Mw/Mn) was 1.16.

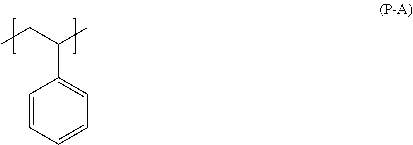

(T)-1: The following compound (T-1)

(C)-1: The following compound (C-1)

(A)-1: Fluorinated surfactant, product name “R-40” manufactured by DIC Corporation

(S)-1: Mixed solvent of propylene glycol monomethyl ether/γ-butyrolactone=75/25 (mass ratio)

(S)-2: Cyclohexanone

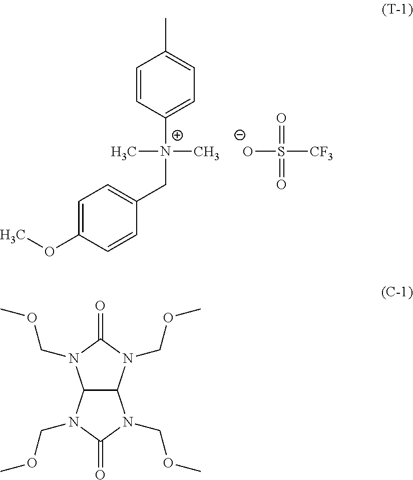

<Formation of Hard Mask Layer>

The hard-mask forming compositions of each example was coated on a silicon wafer using a spinner. Thereafter, baking was performed at a temperature of 300° C. for 90 seconds to form a hard mask layer having a thickness of 1.0 μm.

[Evaluation of Outgassing]

For the hard mask layer of each example formed by the above-mentioned <formation of hard mask layer>, using a thermogravimetric differential thermal analyzer (TG-DTA), the temperature was raised to 240° C. to 400° C. at a rate of 10° C./min. The amount of weight decrease of the hard mask layer when heated at 400° C. as compared with when heated at 240° C. was measured, and occurrence of the outgassing of the hard mask layer was evaluated according to the following criteria. The results are shown in Tables 4 and 5.

Evaluation Criteria

A: Weight reduction rate is 5% or less

B: Weight reduction rate is more than 5% and equal to or less than 10%

C: Weight reduction rate exceeds 10%

[Evaluation of Cracks]

For the hard mask layer of each example formed by the above-mentioned <formation of hard mask layer>, the hard mask layer of each example was observed with an OptoDigital Microscope DSX500, and the occurrence of cracks was evaluated according to the following criteria. The results are shown in Tables 4 and 5.

Evaluation Criteria

A: No cracks are observed in the hard mask layer

B: About 10 cracks were observed in the hard mask layer

C: Many cracks were observed in the hard mask layer

TABLE 4

| | Outgas | | Crack | |
|---|---|---|---|---|
| | Baking | | Baking | |
| | temperature | | temperature | |
| | (° C.) | Evaluation | (° C.) | Evaluation |
| Example 1 | 300 | B | 300 | A |
| Example 2 | 300 | A | 300 | A |
| Example 3 | 300 | A | 300 | A |
| Example 4 | 300 | A | 300 | A |
| Example 5 | 300 | A | 300 | A |
| Example 6 | 300 | A | 300 | A |
| Example 7 | 300 | A | 300 | A |
| Example 8 | 300 | B | 300 | A |
| Example 9 | 300 | A | 300 | B |
| Example 10 | 300 | A | 300 | A |
| Example 11 | 300 | A | 300 | A |
| Example 12 | 300 | B | 300 | B |
| Example 13 | 300 | B | 300 | B |
| Example 14 | 300 | A | 300 | A |
| Example 15 | 300 | A | 300 | A |

TABLE 5

| | Outgas | | Crack | |
|---|---|---|---|---|
| | Baking | | Baking | |
| | temperature | | temperature | |
| | (° C.) | Evaluation | (° C.) | Evaluation |
| Comparative | 300 | C | 300 | C |
| Example 1 | | | | |
| Comparative | 300 | C | 300 | C |
| Example 2 | | | | |
| Comparative | 300 | C | 300 | A |
| Example 3 | | | | |
| Comparative | 300 | A | 300 | C |
| Example 4 | | | | |

From the results shown in Tables 4 and 5, it can be confirmed that the hard-mask forming compositions of Examples 1 to 15 are excellent in low outgassing property and crack resistance as compared with the hard-mask forming compositions of Comparative Examples 1 to 4.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

10: support
11: substrate
12: processing layer
12p: pattern
20: BARC layer
30: resist film
30p: resist pattern
m1, m2: hard mask layer
m1p: resin pattern
m2p: inorganic pattern
100: electronic component

What is claimed is:

1. A hard-mask forming composition comprising:
a resin (P1) containing a structural unit (u11) represented by General Formula (u11-1); and
a resin (P2) containing an aromatic ring and a polar group, provided that the resin (P1) is excluded from the resin (P2): 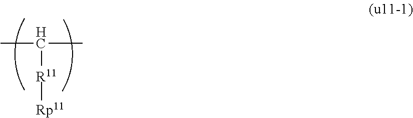
wherein R¹¹ is an aromatic hydrocarbon group which may have a substituent, and Rp¹¹ is an aldehyde group, a group represented by Formula (u-r-1), a group represented by Formula (u-r-2), or a group represented by Formula (u-r-3); 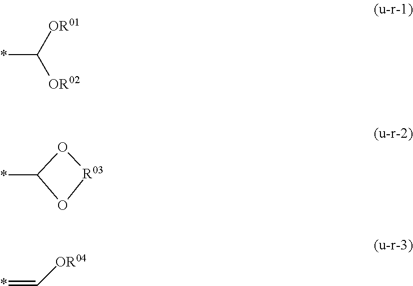
wherein R⁰¹ and R⁰² are each independently a monovalent hydrocarbon group, R⁰³ is a divalent hydrocarbon group, R⁰⁴ is a monovalent hydrocarbon group, and the symbol * represents a bonding site.

2. The hard-mask forming composition according to claim 1,
wherein the resin (P2) includes at least one structural unit selected from the group consisting of a structural unit (u21) represented by General Formula (u21-1), a structural unit (u22) represented by General Formula (u22-1), and a structural unit (u23) represented by General Formula (u23-1); and
at least one structural unit selected from the group consisting of a structural unit (u24) represented by General Formula (u24-1) and a structural unit (u25) represented by General Formula (u25-1): 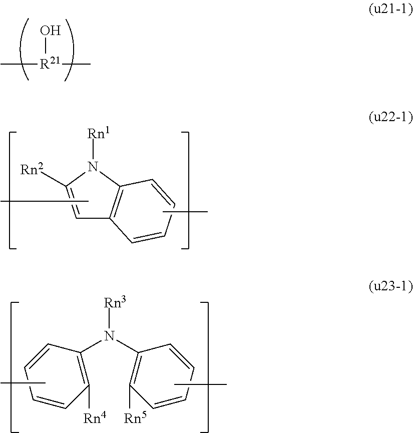
wherein R²¹ represents an aromatic hydrocarbon group which may have a substituent, Rn¹ and Rn² each independently are a hydrogen atom or a monovalent hydrocarbon group, Rn³ to Rn⁵ are each independently a hydrogen atom or a monovalent hydrocarbon group, provided that Rn⁴ and Rn⁵ may be bonded to each other to form a condensed ring with the nitrogen atom in Formula (u23-1); 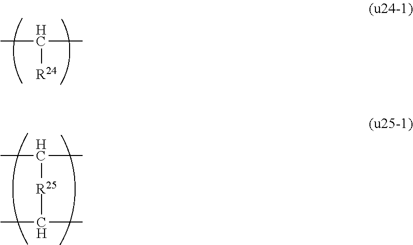
wherein R²⁴ is an aromatic hydrocarbon group which may have a substituent, or a hydrogen atom, and R²⁵ is an aromatic hydrocarbon group which may have a substituent.

3. The hard-mask forming composition according to claim 1,
wherein the resin (P1) further contains a structural unit (u12) represented by General Formula (u12-1): 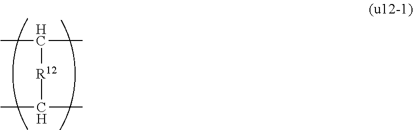
wherein R¹² is an aromatic hydrocarbon group which may have a substituent.

4. The hard-mask forming composition according to claim 3,
wherein the resin (P1) further contains at least one structural unit selected from the group consisting of a structural unit (u13) represented by General Formula (u13-1) and a structural unit (u14) represented by General Formula (u14-1): 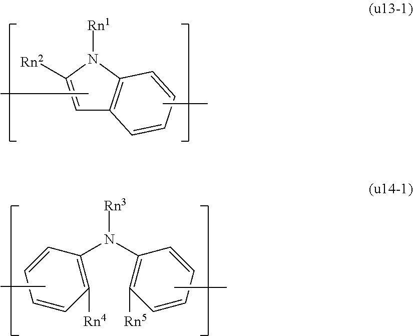
wherein Rn¹ and Rn² are each independently a hydrogen atom or a monovalent hydrocarbon group, Rn³ to Rn⁵ are each independently a hydrogen atom or a monovalent hydrocarbon group, provided that Rn⁴ and Rn⁵ may be bonded to each other to form a condensed ring with the nitrogen atom in Formula (u14-1).

5. The hard-mask forming composition according to claim 1, further comprising a thermal acid generator component.

6. The hard-mask forming composition according to claim 4, further comprising a thermal acid generator component.

7. A method for manufacturing an electronic component, comprising:
forming a hard mask layer (m1) on a support using the hard-mask forming composition according to claim 1; and
processing the support using the hard mask layer (m1) as a mask.

8. A method for manufacturing an electronic component, comprising:
forming a hard mask layer (m1) on a support using the hard-mask forming composition according to claim 1;
forming a hard mask layer (m2) made of an inorganic material on the hard mask layer (m1);
forming a resist film on the hard mask layer (m2);
exposing the resist film to light and developing the exposed resist film to form a resist pattern on the hard mask layer (m2);
etching the hard mask layer (m2) using the resist pattern as a mask to form an inorganic pattern;
etching the hard mask layer (m1) using the inorganic pattern as a mask to form a resin pattern; and
processing the support using the resin pattern as a mask.

9. A method for manufacturing an electronic component, comprising:
forming a hard mask layer (m1) on a support using the hard-mask forming composition according to claim 1;
forming an inorganic pattern made of an inorganic material on the hard mask layer (m1);
etching the hard mask layer (m1) using the inorganic pattern as a mask to form a resin pattern; and
processing the support using the resin pattern as a mask.
